(19) United States
(12) Patent Application Publication
(10) Pub. No.: US 2006/0038201 A1
(43) Pub. Date: Feb. 23, 2006

(54) Layout symmetry constraint checking method and layout symmetry constraint checking apparatus

(76) Inventors: Noriko Shinomiya, Ibaraki (JP); Masaomi Toyama, Takatsuki (JP); Hiroyuki Konishi, Takatsuki (JP)

Correspondence Address: MCDERMOTT WILL & EMERY LLP, 600 13TH STREET, N.W., WASHINGTON, DC, 20005-3096, US

(21) Appl. No.: 11/200,060

(22) Filed: Aug. 10, 2005

(30) Foreign Application Priority Data
Aug. 17, 2004 (JP) 2004-237399

(51) Int. Cl. H01L 27/10

(52) U.S. Cl. 257/206

(57) ABSTRACT

A layout symmetry constraint checking method and apparatus for efficiently checking a layout symmetry constraint is provided. The layout symmetry constraint is checked by performing a first checking step of checking, for example, a match between shapes of a symmetrical element pair for input layout data, a second checking step of checking whether or not a relative positional relationship between elements is contradictory to the layout symmetry constraint, and a third checking step of checking whether or not a geometric placement of the elements satisfies the layout symmetry constraint. When an error occurs in each of the checking steps, a cause for the error is specified and presented to the designer, thereby achieving efficient layout design.

### BACKGROUND OF THE INVENTION

1. Field of the Invention

The present invention relates to a layout symmetry constraint checking method and a layout symmetry constraint checking apparatus. More particularly, the present invention relates to a layout symmetry constraint checking method and a layout symmetry constraint checking apparatus of checking whether or not a layout of a semiconductor integrated circuit, such as an analog circuit, a digital circuit, or the like, is symmetrical.

2. Description of the Background Art

Semiconductor integrated circuits need to be designed in consideration of various layout (placement of elements) constraints. For example, in the case of an analog circuit employing a differential signal, the symmetry of a layout needs to be considered in the design of such a circuit. Conventionally, a number of automatic layout methods considering such a layout constraint have been proposed. In recent years, a method has appeared in which elements are manually placed in a rough manner and then the elements are symmetrically placed using a compaction tool. When layout is manually performed, and even when such an automatic layout method or compaction method is used, there is still a problem with a method of checking whether or not a layout result really satisfies a layout constraint, particularly layout symmetry.

In conventional layout design, a layout constraint is checked manually, such as measurement of a distance between symmetrical elements, visual inspection, or the like. In addition, when an error is detected, a designer itself tries to find and resolve the error.

Therefore, there is a demand for a method of checking a layout constraint. In addition, it is important to inform a designer of a cause of an error.

In the case of a method of adjusting an element into a symmetrical position using a compaction tool, when a symmetrical element pair which has a relative positional relationship which cannot satisfy a layout symmetry constraint is included in input data for compaction, the relative position of the elements cannot be modified by compaction, so that a desired result cannot be obtained. Therefore, when this technique is used, it is particularly necessary to check whether or not there is an error in the positional relationship between elements. In addition, even if there is not an error in the relative positional relationship between elements, it is important to check a layout symmetry constraint with respect to a result of compaction.

Therefore, it is considered that, for example, when an error occurs during a check process of a layout symmetry constraint, a designer is informed of useful error information, such as the type of the error, i.e., whether the error is an error which requires correction of the positional relationship between elements (relatively serious error) or an error which can be resolved by finely adjusting positions of a part of elements (relatively trivial error). This is because if a relatively serious error can be resolved at an early stage of layout design, the layout design can be efficiently carried out.

Hereinafter, a convetional method of manually determining an error will be described with reference to FIGS. 34A to 34C. FIGS. 34A to 34C illustrate a placement of elements in a certain analog circuit. In FIGS. 34A to 34C, rectangles A, B, C, D, and H indicate analog elements, dashed lines 2800 and 2801 indicate symmetry axes. Note that, in conventional layout design, a designer only imagines a symmetry axis and does not draw a symmetry axis as layout data. The dashed lines 2800 and 2801 are only for illustrative purposes. In the example of FIGS. 34A to 34C, for the sake of simplicity, the symmetry axis is assumed to be parallel to the Y axis. In FIGS. 34A to 34C, an element A and an element C, which are a symmetrical element pair requiring symmetry between the elements, an element B and an element D, which are also a symmetrical element pair, a self-symmetrical element H which requires symmetry in itself, are placed. It is assumed that all of these elements form a group and share the same symmetry axis. Such a constraint that elements share a symmetry axis is referred to as a layout symmetry constraint. For the sake of convenience, the layout symmetry constraint is represented by the following expression (1).
γ=((A, C), (B, D), H) (1)

Since the symmetry axis is parallel to the Y axis, the symmetry may be confirmed by confirming that the elements of each symmetrical element pair included in a layout symmetry constraint have the same Y coordinate of the center of gravity, and that the X coordinates of the midpoints of line segments between the centers of gravity of the elements of the symmetrical element pairs and the X coordinate of the center of gravity of the self-symmetrical element are all the same.

When the designer places the elements as illustrated in FIG. 34A, the elements A, B, C, and D have the same Y coordinate of the center of gravity, and the X coordinate of the midpoint of the line segment between the center of gravity of the element A and the center of gravity of the element C, the X coordinate of the midpoint of the line segment between the center of gravity of the element B and the center of gravity of the element D, and the X coordinate of the center of gravity of the element H are the same. Therefore, the symmetrical element pair (A, C) and (B, D) and the self-symmetrical element H are each symmetrical with respect to the dashed line 2800, and satisfy the layout symmetry constraint represented by expression (1).

Alternatively, when the designer places the elements as illustrated in FIGS. 34B and 34C, the X coordinate of the midpoint of the line segment between the center of gravity of the element A and the center of gravity of the element C and the X coordinate of the center of gravity of the element H are the same and are located on the dashed line 2800, however, the X coordinate of the midpoint of the line segment between the center of gravity of the element B and the center of gravity of the element D is located on the dashed line 2801. Thus, these layouts do not satisfy the layout symmetry constraint. Therefore, in the case of the two examples, an error occurs in the placement of the elements.

Causes of the errors in FIGS. 34B and 34C are examined as follows. In FIG. 34B, the element D should be placed on a left side of the element C. The error in FIG. 34B will be understood to be a relatively serious error which requires a change in the positional relationship between the elements. The error in FIG. 34C will be understood to be a relatively trivial error which can be corrected by fine adjustment such that the position of the element D is slightly shift to the right.

When the number of elements is small as illustrated in FIGS. 34A to 34C, a manual method can be used to determine the type of the error, i.e., whether the error is a relatively serious error which requires a change in positional relationship between elements or a relatively trivial error which can be resolved by fine adjustment of positions of elements. However, when the scale of a circuit to be designed is large or the circuit is complicated, it is difficult to manually confirm the correctness of the positional relationship between elements. Therefore, there is a desire for an error determination method which is effective even when the scale of a circuit to be designed is large or the circuit is complicated.

Therefore, a method has been proposed in which a relative positional relationship between elements is represented by a sequence pair and the symmetry of the elements is checked. The sequence pair is a permutation pair (α, β) which represents a relative positional relationship between rectangles placed on a two-dimensional plane. Hereinafter, the sequence pair will be described with reference to FIGS. 35A and 35B.

When a rectangle X and a rectangle Y are placed in a two-dimensional space, the rectangle X is located either a top, bottom, right, or left side of the rectangle Y (see FIG. 35A). In this case, when the rectangle X is located on a left side of the rectangle Y, this placement is represented by a sequence pair (α, β)=(XY, XY). When the rectangle X is located at a right side of the rectangle Y, this placement is represented by (YX, YX). When the rectangle X is located on a top side of the rectangle Y, this placement is represented by (XY, YX). When the rectangle X is located on a bottom side of the rectangle Y, this placement is represented by (YX, XY).

When three or more rectangles are two-dimensionally placed, the procedure of obtaining a sequence pair for two rectangles is repeatedly applied thereto, thereby making it possible to obtain a sequence pair (α, β). In this case, a and β are sequences of three or more rectangles. For example, a relative relationship between rectangles illustrated in FIG. 35B is represented by a sequence pair (α, β)=(ECABFD, FCDEAB). Note that the sequence pair is described in detail in, for example, Yoji Kajitani, “Haichi no Suri: Tasu no Chohokei wo Saishomenseki ni Umekomu (On Packing of Rectangles into a Small Plane Area)”, The Research Meeting of The Institute of Electronics, Information, and Communication Engineers, VLD98-38, September 1998, p. 7-14, and the like.

A method of checking the symmetry of elements using a sequence pair is described in, for example, F. Balasa, et al., “Module Placement for Analog Layout Using the Sequence-Pair Representation”, Proceedings of 36th Design Automation Conference, June 1999, p. 274-279. According to this method, the placement of elements under a layout symmetry constraint is represented by a sequence pair (α, β). Next, for any elements X and Y of a group of elements which are given the layout symmetry constraint, the position of the element X at α is represented by α(X), and the position of the element X at β is represented by β(X). Further, an element which is symmetrical to the element X with respect to a symmetry axis is represented by a sym(X), and an element which is symmetrical to the element Y with respect to a symmetry axis is represented by a sym(Y) (when the element X is a self-symmetrical element, X=sym(X)).

F. Balasa et al. describes that these symmetrical element pairs need to satisfy expression (2) for the elements X and Y in order to satisfy the layout symmetry constraint.
α(X)<α(Y) [symbol] β(sym(Y))<β(sym(X)) (2)

However, expression (2) is a necessary condition for the layout symmetry constraint, but not a sufficient condition. Hereinafter, referring to FIG. 36, a description will be given of the reason why expression (2) is not a sufficient condition for the layout symmetry constraint. In FIG. 36, it is assumed that a layout symmetry constraint γ=((A, C), (B, D)) is given. Next, the placement of these elements is represented by a sequence pair (α, β)=(ABDC, ABDC).

Any arbitrary combination of the elements under the layout symmetry constraint γ, i.e., (A, B), (A, C), (A, D), (B, C), (B, D), and (C, D) satisfies expression (2). For example, in the case of (A, B), α(A)=1, α(B)=2, sym(A)=C, and sym(B)=D. Therefore, P(C)=4, β(D)=3, and β(D)<β(C) when α(A)<α(B). Thus, expression (2) is satisfied.

Note that a similar result is obtained for the other element combinations and will not be explained. However, in FIG. 36, B and D are clearly not symmetrical with respect to a symmetry axis 3000. Therefore, it will be understood that expression (2) is not a sufficient condition for the layout symmetry constraint.

A conventional method of checking the layout symmetry constraint is described in, for example, Japanese Patent Laid-Open Publication No. H06-110978. This publication discloses a checking method employing a technique of finding a positive cycle of a directed graph and a linear programming problem, as a method of finding a contradiction in the layout symmetry constraint.

However, the layout symmetry constraint checking method described in Japanese Patent Laid-Open Publication No. H06-110978 has a problem that it takes a long time to perform a check process. In addition, when a circuit to be designed has a large scale and is complicated, it is difficult to check the symmetry of a layout using conventional manual methods. Further, when a designed circuit does not satisfy the layout symmetry constraint, it is important to inform a designer of the type of the error, i.e., whether the error is a relatively serious error which requires correction of the positional relationship between elements or a relatively trivial error which can be resolved by finely adjusting the positions of elements, for the purpose of increasing the efficiency of layout design.

### SUMMARY OF THE INVENTION

Therefore, an object of the present invention is to provide a layout symmetry constraint checking method and a layout symmetry constraint checking apparatus capable of providing the type of an error to a designer to enable the designer to design a layout more efficiently, concerning a method and an apparatus for checking the layout symmetry of a semiconductor integrated circuit, which is difficult to perform manually in conventional techniques.

A first aspect of the present invention is directed to a method for checking symmetry of a placement of elements included in a circuit, comprising a layout symmetry constraint inputting step of inputting a layout symmetry constraint including information about a symmetrical element pair of two elements which should be placed symmetrical, a layout data inputting step of inputting layout data including information about shapes of the elements and information about the placement of the elements, a first checking step of checking whether or not the shapes of the elements constituting the symmetrical element pair match, based on the element shape information included in the layout data, and a second checking step of obtaining a relative positional relationship between the elements based on the element placement information included in the layout data, and checking whether or not the relative positional relationship satisfies the layout symmetry constraint.

The layout symmetry constraint may include information about a symmetrical element pair of two elements which should be placed line-symmetrical with respect to a symmetry axis.

The method may further comprises a third checking step of checking whether or not a geometric placement of the elements satisfies the layout symmetry constraint, based on the element placement information included in the layout data.

The layout symmetry constraint may further include information about a self-symmetrical element which should be placed itself symmetrical with respect to the symmetry axis.

The first checking step may include checking whether or not X or Y coordinates of representative points of the elements constituting the symmetrical element pair match when a two-dimensional placement of the elements included in the layout data is represented by a Cartesian coordinate system in which the symmetry axis is a Y axis or an X axis.

The third checking step may check whether or not a midpoint of a line segment between representative points of the elements constituting the symmetrical element pair is located on the symmetry axis.

The third checking step may check whether or not a representative point of the self-symmetrical element is located on the symmetry axis.

The second checking step may use a sequence pair to represent the relative positional relationship between the elements, and use the sequence pair to check whether or not the relative positional relationship of the elements satisfies the layout symmetry constraint.

The second checking step may use a first graph indicating a horizontal positional relationship between the elements and a second graph indicating a vertical positional relationship between the elements to represent the relative positional relationship between the elements, and use the first graph and the second graph to check whether or not the relative positional relationship between the elements satisfies the layout symmetry constraint.

The second checking step may use eight directions to represent the relative positional relationship between the elements, the eight directions including top, bottom, left, right, upper right, lower left, upper left, and lower right, and use the eight directions to check whether or not the relative positional relationship between the elements satisfies the layout symmetry constraint.

The layout data may include information about wiring lines connecting the elements and information about a symmetrical wiring line pair which should be placed symmetrical with respect to the symmetry axis. The method may further comprise checking symmetry of the wiring lines.

The layout symmetry constraint may include information about a symmetrical element pair of two elements which should be placed point-symmetrical with respect to a symmetry center.

The method may further comprise a third checking step of checking whether or not a geometric placement of the elements satisfies the layout symmetry constraint, based on the element placement information included in the layout data.

The layout symmetry constraint may further include information about a self-symmetrical element which should be placed itself symmetrical with respect to the symmetry center.

The first checking step may include checking whether or not X and Y coordinates of a midpoint of a line segment between representative points of the elements constituting the symmetrical element pair match the symmetry center when a two-dimensional placement of the elements included in the layout data is represented by a Cartesian coordinate system.

The third checking step may check whether or not a midpoint of a line segment between representative points of the elements constituting the symmetrical element pair is located on the symmetry center.

The third checking step may check whether or not a representative point of the self-symmetrical element is located on the symmetry center.

The layout data may include information about wiring lines connecting the elements and information about a symmetrical wiring line pair which should be placed symmetrical with respect to the symmetry center. The method may further comprise checking symmetry of the wiring lines.

A second aspect of the present invention is directed to a method for checking symmetry of a placement of elements included in a circuit, comprising a layout symmetry constraint inputting step of inputting a layout symmetry constraint including information about a symmetrical element pair of two elements which should be placed symmetrical with respect to a center graphic, a layout data inputting step of inputting layout data including information about shapes of the elements and information about the placement of the elements, an element displaying step of displaying the placement of the elements based on the layout data, a designating step of designating the center graphic defined in the layout symmetry constraint, a center graphic displaying step of displaying the designated center graphic and the placement of the elements, wherein the designated center graphic and the placement of the elements are superposed together, a first checking step of checking whether or not the shapes of the elements constituting the symmetrical element pair match, based on the element shape information included in the layout data, and a second checking step of checking whether or not a geometric placement of all elements included in the layout symmetry constraint satisfies symmetry with respect to the center graphic.

The center graphic may be a symmetry axis. The layout symmetry constraint may include information about a symmetrical element pair of two elements which should be placed symmetrical with respect to the symmetry axis.

The layout symmetry constraint may further include information about a self-symmetrical element which should be placed itself symmetrical with respect to the symmetry axis.

The method may further comprise a third checking step of obtaining a relative positional relationship between the elements based on the element placement information included in the layout data, and checking whether or not the relative positional relationship satisfies the layout symmetry constraint.

The center graphic may be a symmetry center. The layout symmetry constraint may include information about a symmetrical element pair of two elements which should be placed point-symmetrical with respect to the symmetry center.

In this case, the layout symmetry constraint may further include information about a self-symmetrical element which should be placed itself symmetrical with respect to the symmetry center.

The method may further comprise a third checking step of obtaining a relative positional relationship between the elements based on the element placement information included in the layout data, and checking whether or not the relative positional relationship satisfies the layout symmetry constraint.

A third aspect of the present invention is directed to an apparatus for checking symmetry of a placement of elements included in a circuit, comprising layout symmetry constraint inputting means of inputting a layout symmetry constraint including information about a symmetrical element pair of two elements which should be placed symmetrical, layout data inputting means of inputting layout data including information about shapes of the elements and information about the placement of the elements, first checking means of checking whether or not the shapes of the elements constituting the symmetrical element pair match, based on the element shape information included in the layout data, and second checking means of obtaining a relative positional relationship between the elements based on the element placement information included in the layout data, and checking whether or not the relative positional relationship satisfies the layout symmetry constraint.

In this case, the apparatus may further comprise third checking means of checking whether or not a geometric placement of the elements satisfies the layout symmetry constraint, based on the element placement information included in the layout data.

The layout symmetry constraint may include information about a symmetrical element pair of two elements which should be placed line-symmetrical with respect to a symmetry axis.

The layout symmetry constraint may further include information about a self-symmetrical element which should be placed itself symmetrical with respect to the symmetry axis.

The first checking means may include means of checking whether or not X or Y coordinates of representative points of the elements constituting the symmetrical element pair match when a two-dimensional placement of the elements included in the layout data is represented by a Cartesian coordinate system in which the symmetry axis is a Y axis or an X axis.

The layout symmetry constraint may include information about a symmetrical element pair of two elements which should be placed point-symmetrical with respect to a symmetry center.

In this case, the layout symmetry constraint may further include information about a self-symmetrical element which should be placed itself symmetrical with respect to the symmetry center.

The first checking means may include means of checking whether or not X and Y coordinates of a midpoint of a line segment between representative points of the elements constituting the symmetrical element pair match the symmetry center when a two-dimensional placement of the elements included in the layout data is represented by a Cartesian coordinate system.

A fourth aspect of the present invention is directed to an apparatus for checking symmetry of a placement of elements included in a circuit, comprising layout symmetry constraint inputting means of inputting a layout symmetry constraint including information about a symmetrical element pair of two elements which should be placed symmetrical with respect to a center graphic, layout data inputting means of inputting layout data including information about shapes of the elements and information about the placement of the elements, element displaying means of displaying the placement of the elements based on the layout data, designating means of designating the center graphic defined in the layout symmetry constraint, center graphic displaying means of displaying the designated center graphic and the placement of the elements, wherein the designated center graphic and the placement of the elements are superposed together, first checking means of checking whether or not the shapes of the elements constituting the symmetrical element pair match, based on the element shape information included in the layout data, and second checking means of checking whether or not a geometric placement of all elements included in the layout symmetry constraint satisfies symmetry with respect to the center graphic.

In this case, the center graphic may be a symmetry axis. The layout symmetry constraint may include information about a symmetrical element pair of two elements which should be placed symmetrical with respect to the symmetry axis.

The layout symmetry constraint may further include information about a self-symmetrical element which should be placed itself symmetrical with respect to the symmetry axis.

The apparatus may further comprise third checking means of obtaining a relative positional relationship between the elements based on the element placement information included in the layout data, and checking whether or not the relative positional relationship satisfies the layout symmetry constraint.

Alternatively, the center graphic may be a symmetry center. The layout symmetry constraint may include information about a symmetrical element pair of two elements which should be placed point-symmetrical with respect to the symmetry center.

In this case, the layout symmetry constraint may further include information about a self-symmetrical element which should be placed itself symmetrical with respect to the symmetry center.

The apparatus may further comprise third checking means of obtaining a relative positional relationship between the elements based on the element placement information included in the layout data, and checking whether or not the relative positional relationship satisfies the layout symmetry constraint.

The layout symmetry constraint checking method of the present invention comprises a first checking step of checking whether or not shapes of elements constituting a symmetrical element pair match and whether or not the X coordinates of the centers of gravity of the elements constituting the symmetrical element pair match, a second checking step of obtaining a relative positional relationship between the elements and checking whether or not the relative positional relationship satisfies a layout symmetry constraint, and a third checking step of checking whether or not a geometric placement of the elements satisfies the layout symmetry constraint. Thereby, it is possible to reliably check a layout symmetry constraint for a circuit having a number of elements or a complicated circuit which are difficult to check manually.

Since the layout symmetry constraint checking method of the present invention includes the second checking step of obtaining a relative positional relationship between the elements and checking whether or not the relative positional relationship satisfies a layout symmetry constraint. When a placement of elements does not satisfy the layout symmetry constraint, it is possible to determine the type of the error, i.e., whether the error is a relatively serious error which requires a change in positional relationship between the elements, or a relatively trivial error which can be resolved by finely adjusting positions of the elements. The type of the error is presented to the designer, thereby making it possible to perform layout design efficiently.

Further, a sequence pair may be used in the second checking step of the layout symmetry constraint checking method of the present invention, resulting in a quick determination of the relative positional relationship. Therefore, it is possible to quickly detect an error when the relative positional relationship between elements does not satisfy a layout symmetry constraint.

Further, according to the layout symmetry constraint checking method of the present invention, it is possible to check symmetry of wiring lines which should be placed symmetrical to a common symmetry axis.

Further, according to the layout symmetry constraint checking method of the present invention, a symmetry axis is designated by the designer and is displayed on a screen, whereby an element which does not satisfy the layout symmetry constraint is specified. Since an element which does not satisfy the layout symmetry constraint is presented to the designer, it is possible to perform layout design efficiently.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram illustrating a structure of a layout symmetry constraint checking apparatus for use in performing a layout symmetry constraint checking method according to each embodiment of the present invention;

FIG. 2 is a flowchart illustrating a layout symmetry constraint checking method according to a first embodiment of the present invention;

FIG. 3 is a diagram illustrating an exemplary placement of elements for which a layout symmetry constraint is checked using the layout symmetry constraint checking method of the first embodiment of the present invention;

FIG. 4 is a flowchart illustrating a first check procedure of the layout symmetry constraint checking method of the first embodiment of the present invention;

FIG. 5 is a diagram illustrating an exemplary placement of elements in which an error occurs in the first checking procedure of the layout symmetry constraint checking method of the first embodiment of the present invention;

FIG. 6 is a flowchart illustrating a second check procedure of the layout symmetry constraint checking method of the first embodiment of the present invention;

FIG. 7 is a diagram illustrating an exemplary placement of elements in which an error occurs in the second checking procedure of the layout symmetry constraint checking method of the first embodiment of the present invention;

FIG. 8 is a flowchart illustrating a third check procedure of the layout symmetry constraint checking method of the first embodiment of the present invention;

FIG. 9 is a diagram illustrating an exemplary placement of elements in which an error occurs in the third checking procedure of the layout symmetry constraint checking method of the first embodiment of the present invention;

FIG. 10 is a flowchart illustrating a second check procedure of a layout symmetry constraint checking method according to a second embodiment of the present invention;

FIG. 11A is a diagram illustrating an exemplary placement of elements for which a layout symmetry constraint is checked using the layout symmetry constraint checking method of the second embodiment of the present invention;

FIG. 11B is a diagram illustrating an exemplary horizontal graph in the example of FIG. 11A;

FIG. 11C is a diagram illustrating an exemplary vertical graph in the example of FIG. 11A;

FIG. 12 is a flowchart illustrating a checking procedure using the horizontal graph in the layout symmetry constraint checking method of the second embodiment of the present invention;

FIG. 13 is a diagram illustrating a result of the checking procedure using the horizontal graph in the layout symmetry constraint checking method of the second embodiment of the present invention;

FIG. 14A is a diagram illustrating an exemplary placement of elements in which an error occurs in a second checking procedure of the layout symmetry constraint checking method of the second embodiment of the present invention;

FIG. 14B is a diagram illustrating an exemplary horizontal graph in the example of FIG. 14A;

FIG. 14C is a diagram illustrating a result of the checking procedure using the horizontal graph of FIG. 14B;

FIG. 15A is a diagram illustrating ranges occupied by the elements A and B;

FIG. 15B is a diagram illustrating a definition of eight directions for use in a layout symmetry constraint checking method according to a third embodiment of the present invention;

FIG. 16 is a flowchart illustrating a second checking procedure in the layout symmetry constraint checking method of the third embodiment of the present invention;

FIG. 17A is a diagram illustrating an exemplary placement of elements for which a layout symmetry constraint is checked using the layout symmetry constraint checking method of the third embodiment of the present invention;

FIG. 17B is a diagram illustrating another exemplary placement of elements for which a layout symmetry constraint is checked using the layout symmetry constraint checking method of the third embodiment of the present invention;

FIG. 18 is a flowchart illustrating a layout symmetry constraint checking method according to a fourth embodiment of the present invention;

FIG. 19 is a flowchart illustrating a first checking procedure of the layout symmetry constraint checking method of the fourth embodiment of the present invention;

FIG. 20 is a flowchart illustrating a second checking procedure of the layout symmetry constraint checking method of the fourth embodiment of the present invention;

FIG. 21 is a flowchart illustrating a third checking procedure of the layout symmetry constraint checking method of the fourth embodiment of the present invention;

FIG. 22 is a flowchart illustrating a layout symmetry constraint checking method according to a fifth embodiment of the present invention;

FIG. 23 is a flowchart illustrating a procedure of checking symmetry of wiring lines in the layout symmetry constraint checking method of the fifth embodiment of the present invention;

FIG. 24A is a diagram illustrating an exemplary placement of wiring lines for which a layout symmetry constraint is checked using the layout symmetry constraint checking method of the fifth embodiment of the present invention;

FIG. 24B is a diagram illustrating another exemplary placement of wiring lines for which a layout symmetry constraint is checked using the layout symmetry constraint checking method of the fifth embodiment of the present invention;

FIG. 25 is a flowchart illustrating a layout symmetry constraint checking method according to a sixth embodiment of the present invention;

FIG. 26 is a flowchart illustrating a procedure of checking a layout symmetry constraint using a symmetry axis in the layout symmetry constraint checking method of the sixth embodiment of the present invention;

FIG. 27A is a diagram illustrating an exemplary placement of elements for which a layout symmetry constraint is checked using the layout symmetry constraint checking method of the sixth embodiment of the present invention;

FIG. 27B is a diagram illustrating another exemplary placement of elements for which a layout symmetry constraint is checked using the layout symmetry constraint checking method of the sixth embodiment of the present invention;

FIG. 28 is a flowchart illustrating a first checking procedure of a layout symmetry constraint checking method according to a seventh embodiment of the present invention;

FIG. 29 is a flowchart illustrating a third checking procedure of the layout symmetry constraint checking method of the seventh embodiment of the present invention;

FIG. 30 is a diagram illustrating an exemplary placement of elements for which a layout symmetry constraint is checked using a layout symmetry constraint checking method according to an eighth embodiment of the present invention;

FIG. 31 is a diagram illustrating an exemplary placement of elements in which an error occurs in the first checking procedure of the layout symmetry constraint checking method of the eighth embodiment of the present invention;

FIG. 32 is a diagram illustrating an exemplary placement of wiring lines for which a layout symmetry constraint is checked using a layout symmetry constraint checking method according to a ninth embodiment of the present invention;

FIG. 33 is a flowchart illustrating a procedure of checking symmetry of wiring lines using the layout symmetry constraint checking method of the ninth embodiment of the present invention;

FIG. 34A is a diagram illustrating a conventional layout symmetry constraint checking method;

FIG. 34B is a diagram illustrating another conventional layout symmetry constraint checking method;

FIG. 34C is a diagram illustrating still another conventional layout symmetry constraint checking method;

FIG. 35A is a diagram illustrating a method of representing a relative positional relationship using a sequence pair;

FIG. 35B is a diagram illustrating another method of representing a relative positional relationship using a sequence pair; and

FIG. 36 is a diagram illustrating an exemplary layout which does not satisfy a layout symmetry constraint.

### DESCRIPTION OF THE PREFERRED EMBODIMENTS

Hereinafter, layout symmetry constraint checking methods according to first to ninth embodiments of the present invention will be described with reference to the accompanying drawings.

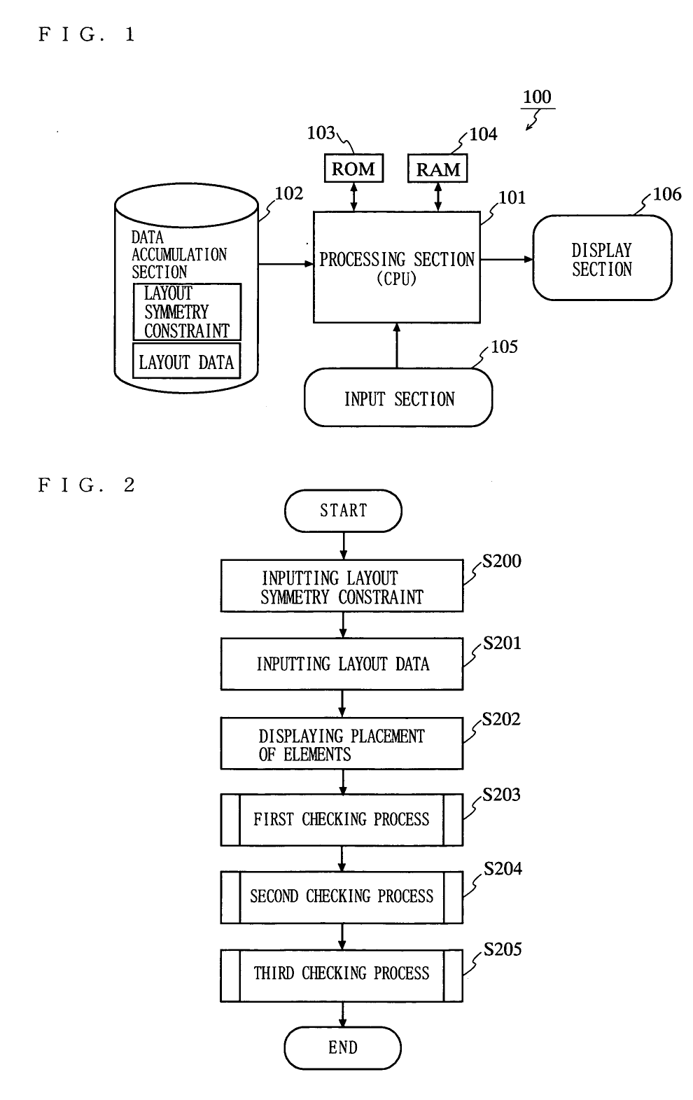

The method of each embodiment is performed using a layout symmetry constraint checking apparatus illustrated in FIG. 1. The layout symmetry constraint checking apparatus 100 of FIG. 1 comprises a processing section (CPU) 101, a data accumulation section 102, a ROM 103, a RAM 104, an input section 105, and a display section 106. In the data accumulation section 102, design data are accumulated, including a layout symmetry constraint (e.g., information about a symmetrical element pair to be placed symmetrical with respect to a symmetry axis, information about a self-symmetrical element to be placed symmetrical with respect to the symmetry axis, information about elements to be placed symmetrical with respect to a common symmetry axis), layout data (e.g., information about shapes of elements, information about a placement of elements, etc.), and the like. In the ROM 103, a program and data for checking the layout symmetry constraint are stored. The processing section 101 performs various processes with respect to data accumulated in the data accumulation section 102 based on the program stored in the ROM 103. The RAM 104 functions as a working memory. The input section 105 receives commands to execute the program, resolve an error, designate a symmetry axis, and the like. The display section 106 displays a result of layout design processed in the processing section 101.

### First Embodiment

FIG. 2 is a flowchart illustrating a procedure of processing a layout symmetry constraint checking method according to a first embodiment of the present invention. Hereinafter, the first embodiment of the present invention will be described with reference to FIG. 2.

When receiving a command to execute a program from a designer through the input section 105, the processing section 101 receives information about a symmetrical element pair and a self-symmetrical element to be placed symmetrical with respect to a common symmetry axis, i.e., a layout symmetry constraint, from the data accumulation section 102 (step S200). Next, the processing section 101 receives layout data including information about shapes of elements and information about a placement of elements from the data accumulation section 102 (step S201). The display section 106 displays a placement of elements on a screen based on the layout data (step S202).

For example, it is assumed that the layout data input to the processing section 101 in step S200 and step S201 are as illustrated in FIG. 3. The processing section 101 receives symmetrical element pairs (A, C), (B, D), and (E, F), self-symmetrical element pairs H and I, a layout symmetry constraint γ=((A, C), (B, D), (E, F), H, I), and shape information and placement information of the elements A to I. Although the number of elements is small in the example of FIG. 3 for the sake of simplicity, the layout symmetry constraint checking method of the first embodiment is effective even when the number of elements is large.

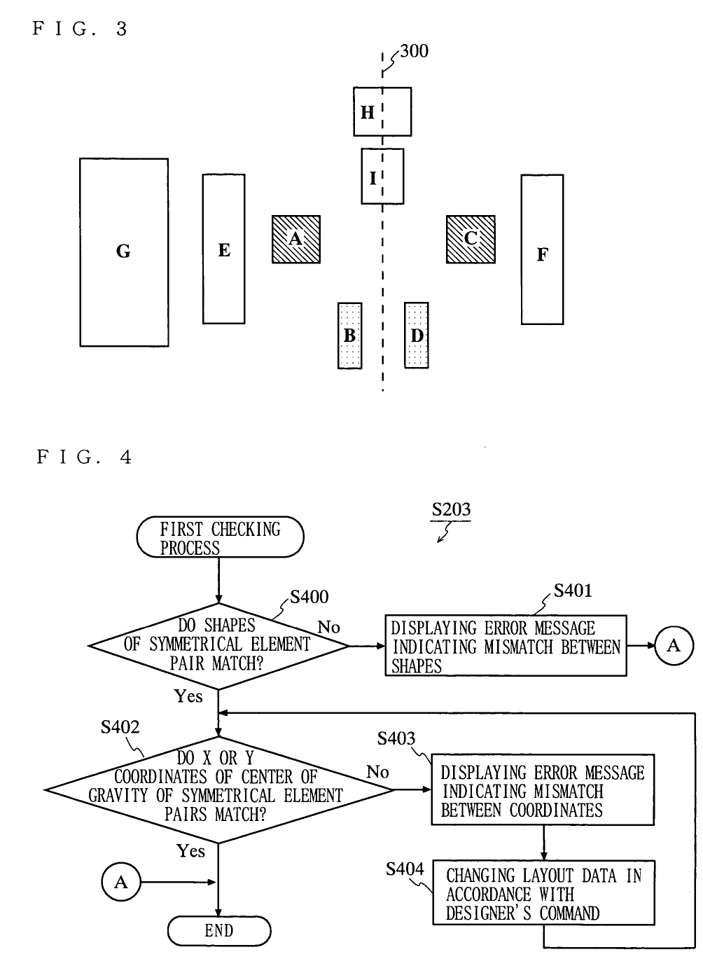

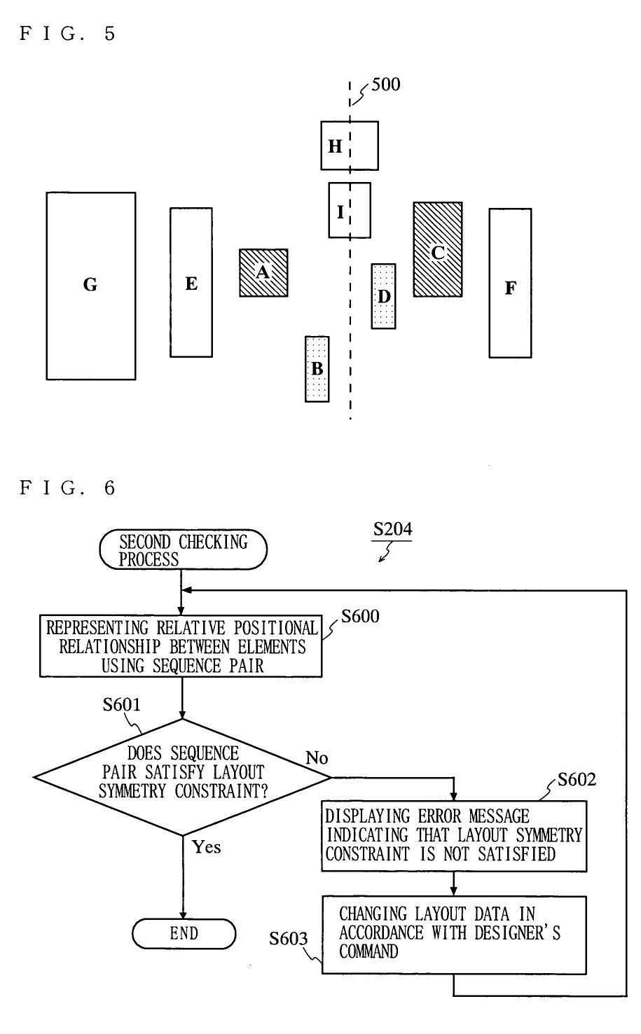

Thereafter, the processing section 101 performs first to third check processes (step S203 to step S205). The processing section 101 checks a match between shapes of elements constituting a symmetrical element pair, and a match between the X or Y coordinates of the centers of gravity of elements constituting a symmetrical element pair in the first check process; whether or not a relative positional relationship between elements satisfies the layout symmetry constraint in the second check process; and whether or not a geometric placement of elements satisfies the layout symmetry constraint in the third check process. Hereinafter, the first to third check processes will be described with reference to FIGS. 4 to 9.

FIG. 4 is a flowchart illustrating details of the first check process. In the first check process, as in FIG. 4, the processing section 101 determines whether or not the shapes of elements constituting a symmetrical element pair match (step S400). In step S400, the processing section 101 may rotate, or move upward, downward, rightward, or leftward an element in accordance with a command from a designer, and then determines whether or not the shapes of elements constituting a symmetrical element pair match.

When the shapes of the elements do not match, the processing section 101 detects an error and outputs a command to display an error message to the display section 106. Based on the command from the processing section 101, the display section 106 displays an error message indicating that the shapes of elements constituting a symmetrical element pair do not match (step S401). Then, the processing section 101 ends the first check process.

When it is determined in step S400 that the shapes of all the elements match, the processing section 101 checks whether or not the X or Y coordinates of the centers of gravity of the elements constituting the symmetrical element pair match (step S402). When the symmetry axis is parallel to the Y axis, it is determined whether or not the Y coordinates of the centers of gravity of the elements constituting the symmetrical element pair match. When the symmetry axis is parallel to the X axis, it is determined whether or not the X coordinates of the centers of gravity of the elements constituting the symmetrical element pair match. When the X or Y coordinates of the centers of gravity of the elements constituting the symmetrical element pair do not match, the processing section 101 detects an error and outputs a command to display an error message to the display section 106.

Based on the command from the processing section 101, the display section 106 displays an error message indicating that the X or Y coordinates of the centers of gravity of the elements constituting the symmetrical element pair do not match (step S403). Based on the error message, the designer changes the placement of the elements via the input section 105. The processing section 101 changes the layout data based on a process input by the designer (step S404), and performs checking again (step S402). When all errors are resolved, the processing section 101 ends the first check process.

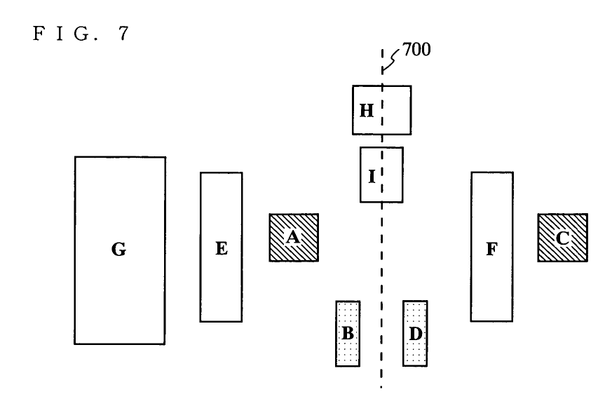

For example, when the layout data input in step S201 is as illustrated in FIG. 5, the elements A and C of a symmetrical element pair do not have the same shape. Therefore, in this case, the display section 106 displays an error message indicating that the shapes of the elements A and C do not match.

Also, in the placement of elements in FIG. 5, the elements B and D of a symmetrical element pair do not have the same Y coordinate of the center of gravity. Therefore, in this case, the display section 106 displays an error message indicating that the Y coordinates of the centers of gravity of the elements B and D do not match.

FIG. 6 is a flowchart illustrating details of the second check process. In the second check process, as illustrated in FIG. 6, the processing section 101 represents a relative positional relationship between elements using a sequence pair (step S600). Next, the processing section 101 checks whether or not the relative positional relationship between elements represented by a sequence pair satisfies the layout symmetry constraint input in step S200 (step S601). In this case, the checking is performed using the above-described expression (2). If expression (2) is satisfied for all combinations of elements included in the layout symmetry constraint, it is determined that the relative positional relationship between the elements satisfies the layout symmetry constraint.

In the checking of step S601, when there is a combination of elements which does not satisfy expression (2), the processing section 101 determines that an error occurs and outputs a command to display an error message to the display section 106. Based on the command from the processing section 101, the display section 106 displays an error message indicating that the relative positional relationship does not satisfy the layout symmetry constraint. When the designer changes the placement of the elements via the input section 105, the processing section 101 changes the layout data based on a process input by the designer (step S603), and performs checking again (step S600 and step S601). When all errors are resolved, the processing section 101 ends the second check process.

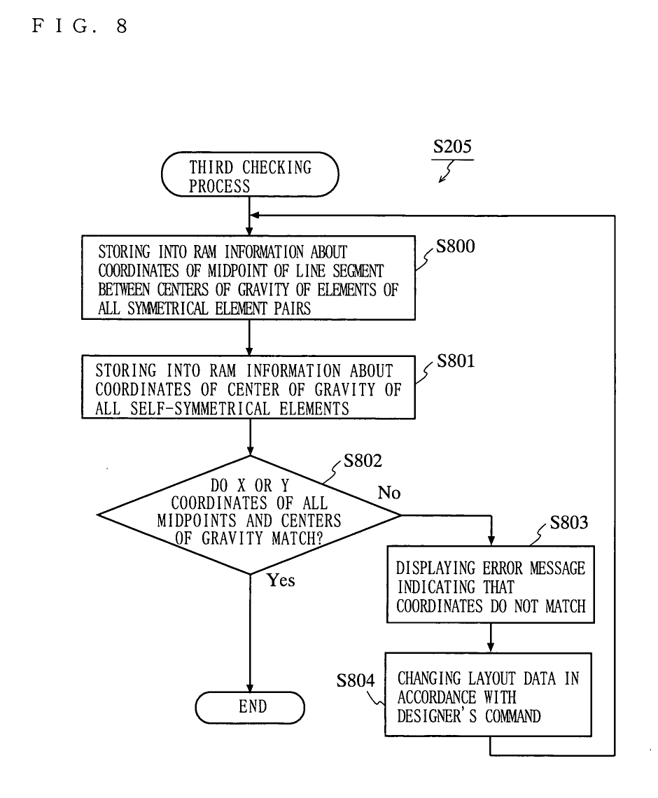

For example, when the layout data input in step S201 is as illustrated in FIG. 7, (A, C) and (E, F) do not satisfy the condition of expression (2). Therefore, the display section 106 displays an error message indicating that the relative positional relationship between the elements A, C, E, and F does not satisfy the layout symmetry constraint.

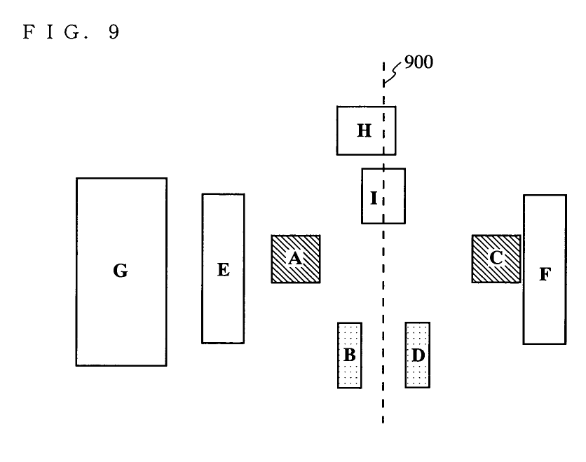

FIG. 8 is a flowchart illustrating details of the third check process. In the third check process, as illustrated in FIG. 8, the processing section 101 obtains the coordinates of the midpoint of the line segment between the centers of gravity of elements constituting a symmetrical element pair for all the symmetrical element pairs, and writes the results into the RAM 104 (step S800). Next, the processing section 101 obtains the coordinates of the centers of gravity of all the self-symmetrical elements, and writes the results into the RAM 104 (step S801). The processing section 101 checks whether or not the X coordinates (or Y coordinates) of the midpoints of the line segments between the centers of gravity of the elements constituting the symmetrical element pair(s) and the X coordinates (or Y coordinates) of the centers of gravity of the self-symmetrical element(s) all match (step S802).

When the symmetry axis is parallel to the Y axis, the processing section 101 checks a match between X coordinates. When the symmetry axis is parallel to the X axis, the processing section 101 checks a match between Y coordinates. In the checking of step S802, when detecting that the X or Y coordinate value of a symmetrical element pair or a self-symmetrical element fails the match, the processing section 101 outputs a command to display an error message to the display section 106.

Based on the command from the processing section 101, the display section 106 displays an error message indicating that all of the midpoints and the X or Y coordinates of the centers of gravity do not match (step S803). If the designer changes the placement of the elements via the input section 105, the processing section 101 changes the layout data based on a process input by the designer (step S804), and performs checking again (step S800 to step S802). When all errors are resolved, the processing section 101 ends the third check process.

For example, when the layout data input in step S201 is as illustrated in FIG. 9, the midpoint of the line segment between the elements A and C and the X coordinate of the center of gravity of the self-symmetrical element H do not match the X coordinate of the midpoints of the other symmetrical element pairs and the X coordinate of the center of gravity of the other self-symmetrical element. Therefore, the display section 106 displays an error message indicating that the X coordinates of the midpoints of the symmetrical element pairs and the X coordinates of the centers of gravity of the self-symmetrical elements do not match.

As described above, according to the layout symmetry constraint checking method of the first embodiment, an error message is displayed in each step of the check process, thereby making it possible to easily confirm what error occurs. In addition, since an error that the relative positional relationship between elements does not satisfy the layout symmetry constraint is detected, the designer can confirm whether the detected error is relatively trivial or serious. Particularly, by using a sequence pair, the relative positional relationship can be determined quickly, thereby making it possible to produce a layout design efficiently.

In the first embodiment, the case where there is a single symmetry axis is illustrated. When there are a plurality of symmetry axes in a circuit, the processing section 101 receives layout symmetry constraints corresponding to these symmetry axes, and checks the received layout symmetry constraints, thereby making it possible to check layout symmetry for each symmetry axis in the circuit.

### Second Embodiment

Next, a layout symmetry constraint checking method according to a second embodiment of the present invention will be described. The layout symmetry constraint checking method of the second embodiment is different from that of the first embodiment in the second check process. Therefore, only the second check process will be hereinafter described.

In the second embodiment, as is different from the first embodiment, a relative positional relationship between elements is represented using a horizontal graph GH(N, E) and a vertical graph GV(N, E) which are graphs composed of a set of nodes and a set of edges (N represents a node and E represents an edge).

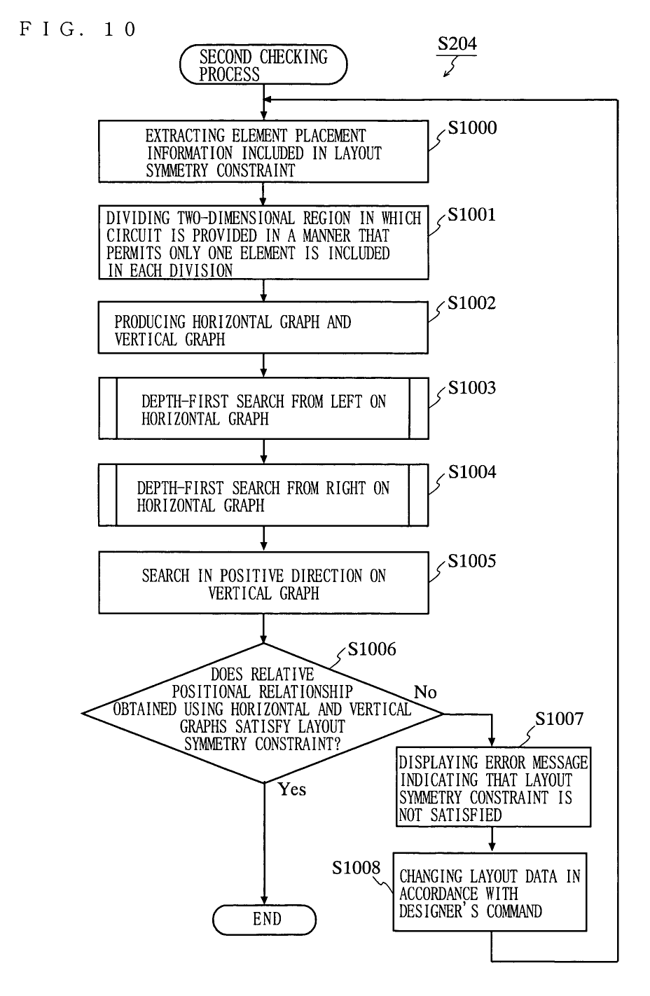

FIG. 10 is a flowchart illustrating details of a second check process of the second embodiment. In the second check process, as illustrated in FIG. 10, the processing section 101 extracts information about a placement of elements included in a layout symmetry constraint (step S1000). Next, the processing section 101 divides a two-dimensional region in which the elements are placed, in a manner which permits a single extracted element to be included in each division (step S1001). Next, the processing section 101 produces a horizontal graph and a vertical graph which represent the relative positional relationship between the elements, with respect to the divided region (step S1002).

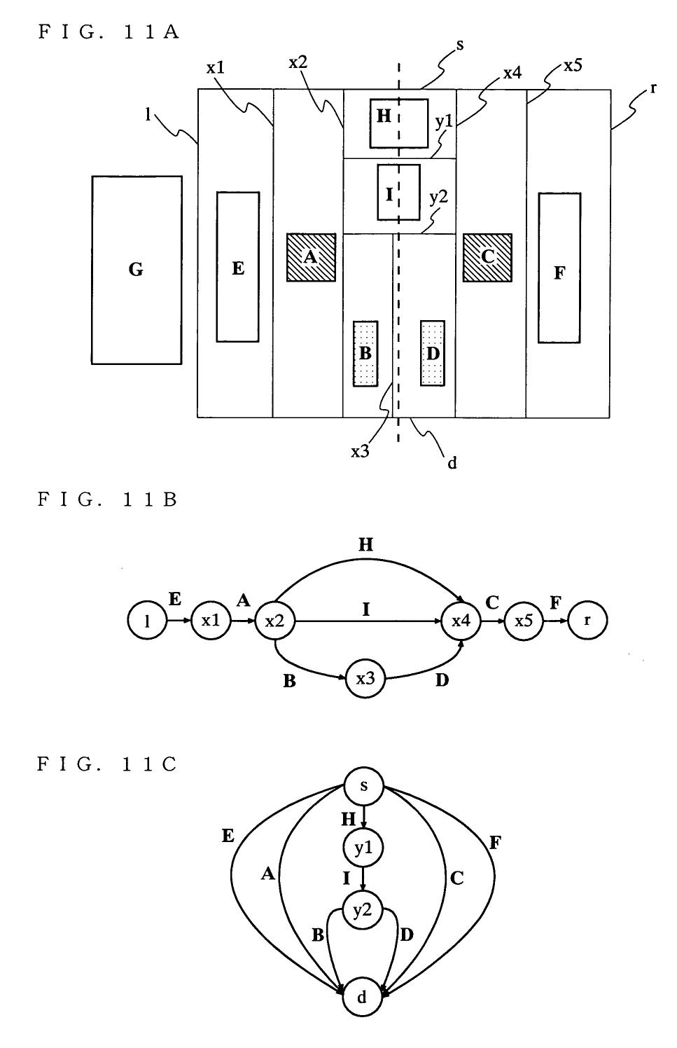

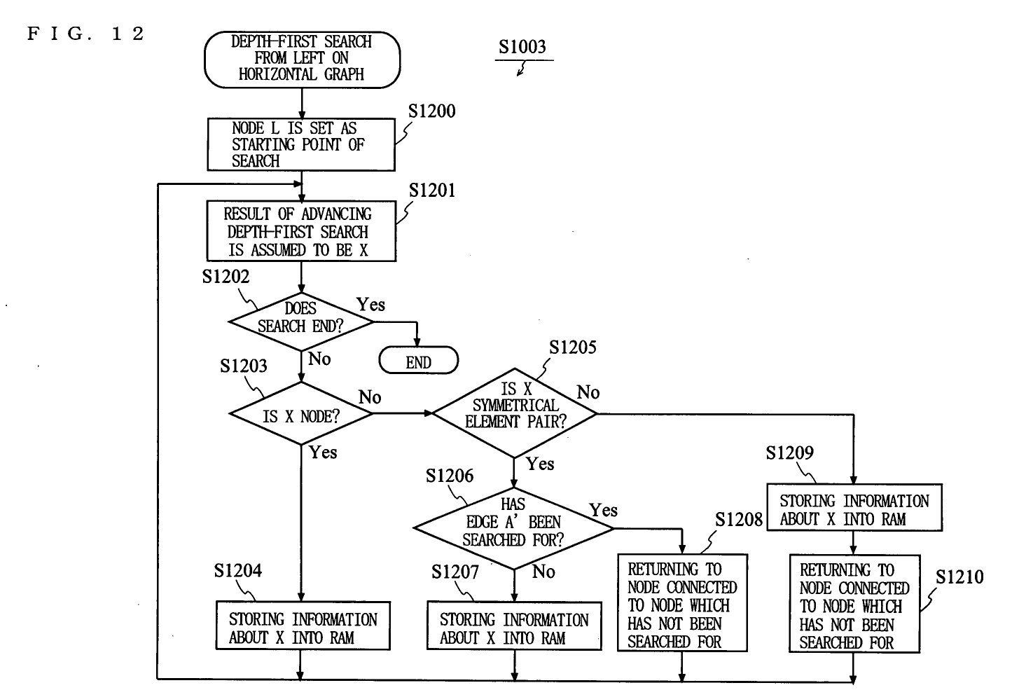

The horizontal graph represents relative positions in a horizontal direction of rectangles placed on a two-dimensional plane. The vertical graph represents relative positions in a vertical direction of rectangles placed on a two-dimensional plane. When these graphs are produced, the two-dimensional region in which the elements are placed is divided into a plurality of rectangular regions, each of which includes one element (see FIG. 11A). Sides of these regions include a side parallel to the X axis (hereinafter referred to as a horizontal side) and a side parallel to the Y axis (hereinafter referred to as a vertical side).

The horizontal graph has a node corresponding to each vertical side. When a certain region has two vertical sides, the horizontal graph has an edge connecting the nodes corresponding to the two vertical sides, which are labeled with the name of a element located in the region as a label (see FIG. 11B). Note that, in the horizontal graph of FIG. 11B, a node corresponding to the leftmost vertical side is represented by 1, and a node corresponding to the rightmost vertical side is represented by r.

Similarly, the vertical graph has a node corresponding to each horizontal side. When a certain region has two horizontal sides, the vertical graph has an edge connecting the two nodes corresponding to the two horizontal sides, which are labeled with the name of a element located in the region as a label (FIG. 11C). Note that, in the vertical graph of FIG. 11C, the uppermost horizontal side is represented by s, and the lowermost horizontal side is represented by d.

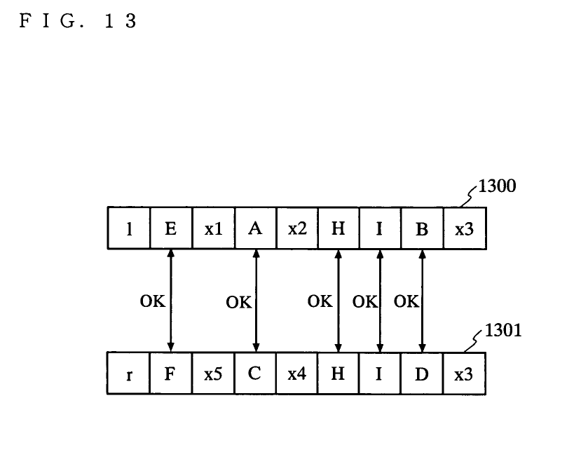

In the horizontal graph thus produced, the processing section 101 performs a depth-first search from left and a depth-first search from right (step S1003 and step S1004). Hereinafter, the relative positional relationship checking method will be described with reference to a flowchart illustrated in FIG. 12, where the depth-first search from left is illustrated.

FIG. 12 is a flowchart illustrating a method of performing a depth-first search from left with respect to a horizontal graph. Hereinafter, the method of performing depth-first search from left will be described with reference to the flowchart of FIG. 12. The processing section 101 starts the depth-first search where the node 1 is a starting point (step S1200). Next, the processing section 101 advances the depth-first search by one step, and the result of the advance is assumed to be X (step S1201). The processing section 101 determines whether or not X is a node (step S1203). When an object to be searched is a node, the processing section 101 writes information about the search object X into the RAM 104 (step S1204). The search object X is written into the RAM 104 by using the RAM 104 in a manner similar to that of an FIFO memory to write information to be searched, in order of search.

When the search object X is an edge (No in step S1203), the processing section 101 determines whether or not the search object X is an edge corresponding to an element constituting a symmetrical element pair (step S1205). When the search object X is an edge (hereinafter referred to as an edge A) corresponding to an element (hereinafter referred to as an element A), the processing section 101 determines whether or not an edge A′ corresponding to an element A′ which constitutes the symmetrical element pair with the element A has been searched for (step S1206) When the edge A′ has not been searched for, the processing section 101 writes information about the search object X into the RAM 104 (step S1207), and continues the search. When the edge A′ has been searched for, the processing section 101 returns to a node connected to a node which has not been searched for (step S1208), and continues the search.

When the search object X is an edge and is not an edge corresponding to an element constituting a symmetrical element pair (No in step S1205), the search object X is an edge corresponding to a self-symmetrical element (No in step S1205). In this case, the processing section 101 writes information about the search object X into the RAM 104 (step S1209), and returns to a node connected to a node which has not been searched for (step S1210). The above-described depth-first search is performed until no search object remains. When no search object remains, the processing section 101 ends the search process (Yes in step S1202). The depth-first search from right (step S1004) is performed in a manner similar to that described above, where the node r is a starting point.

In the horizontal graph of FIG. 11B, when the depth-first search from left is performed, the processing section 101 writes information about the node 1 (staring point) into the RAM 104. Next, when the search is advanced by one step, the search object X becomes the edge E. The element E and the element F constitute a symmetrical element pair. Therefore, in step S1206, the processing section 101 determines whether or not the edge F has been searched for. At this point, the edge F has not been searched for. Therefore, the processing section 101 writes information about the edge E into the RAM 104, and continues the search.

When the search is continued in the above-described manner and the search object becomes the edge H corresponding to the element H, since the element H is a self-symmetrical element, the processing section 101 writes information about the edge H into the RAM 104 and returns to a node connected to a node which has not been searched for. When the search for the edge B ends and the search object becomes the edge D, since the edge B corresponding to the element B which constitutes a symmetrical element pair with the element D has been searched for, the processing section 101 returns to a node connected to a node which has not been searched for.

When ending checking the layout symmetry constraint using the horizontal graph, the processing section 101 then checks the layout symmetry constraint using the vertical graph (step S1005). The processing section 101 searches the vertical graph in a positive direction from a node s (source) to a node d (drain).

Concerning any elements A and B, and elements A′ and B′ constituting respective symmetrical element pairs with the elements A and B, respectively, it is assumed that there is a path on which the element A is searched for earlier than the element B. In this case, the processing section 101 determines whether or not there is a path on which the element A′ is searched for earlier than the element B′. When there is a path on which the element B′ is searched for earlier than the element A′, the processing section 101 determines that the relative positional relationship between the elements does not satisfy the layout symmetry constraint, and writes error information into the RAM 104.

When the process of step S1004 ends, a result of search of the horizontal graph from left and a result of search of the horizontal graph from right are accumulated in the RAM 104. Based on the two search results, the processing section 101 determines that the relative positional relationship between the elements satisfy the layout symmetry constraint (step S1006). In step S1006, when, for all of the symmetrical element pairs, the elements constituting each symmetrical element pair appear at the same ordinal place in a result of search from left and a result of search from right, the processing section 101 determines that the relative positional relationship between the elements satisfies the layout symmetry constraint. Otherwise, the processing section 101 determines that the relative positional relationship between the elements does not satisfy the layout symmetry constraint.

At the time when the process of step S1005 ends, error information in step S1005 may be accumulated in the RAM 104. Therefore, the processing section 101 references the RAM 104 to examine a result of checking the layout symmetry constraint using the vertical graph. When the error information is accumulated in the RAM 104, the processing section 101 determines that the relative positional relationship between the elements does not satisfy the layout symmetry constraint (No in step S1006).

When the relative positional relationship between the elements does not satisfy the layout symmetry constraint, the processing section 101 outputs a command to display an error message to the display section 106. Based on the command from the processing section 101, the display section 106 displays an error message indicating the relative positional relationship does not satisfy the layout symmetry constraint (step S1007). When the designer changes the placement of the elements via the input section 105, the processing section 101 changes the layout data based on a process input by the designer (step S1008), and performs checking again (step S1000 to step S1006). When all errors are resolved, the processing section 101 ends the second check process.

For example, when a depth-first search is performed in the horizontal graph of FIG. 11B, a result of search from left (1300) and a result of search from right (1301) are obtained as illustrated in FIG. 13. In this case, concerning the symmetrical element pair (A, C), data of the element A appears at the fourth place in the result of search from left (1300), and data of the element C appears at the fourth place in the result of search from right (1301). Thus, the elements A and C appear at the same ordinal place in the result of search from left (1300) and the result of search from right (1301). Similar results are obtained for the symmetrical element pairs (B, D) and (E, F).

Concerning the self-symmetrical element H, data of the element H appears at the sixth place in the result of search from left (1300) and at the sixth place in the result of search from right (1301). Thus, the data of the element H appears the same ordinal place in the result of search from left (1300) and the result of search from right (1301). A similar result is obtained for the self-symmetrical element I. Therefore, the processing section 101 determines that the relative positional relationship between the elements satisfies the layout symmetry constraint, based on the horizontal graph of FIG. 11B, in step S1006.

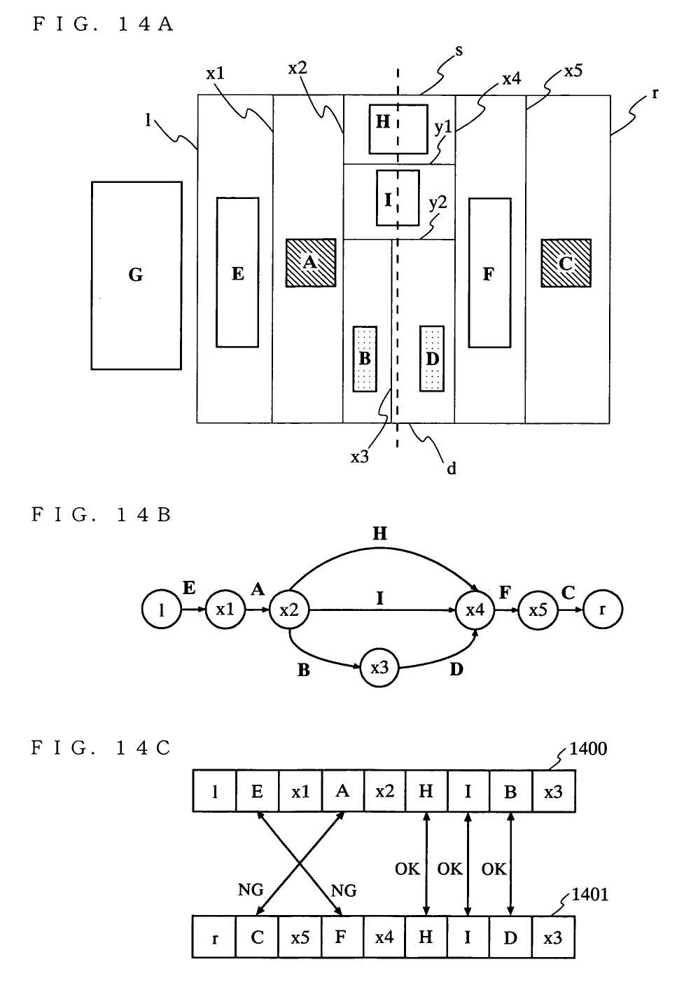

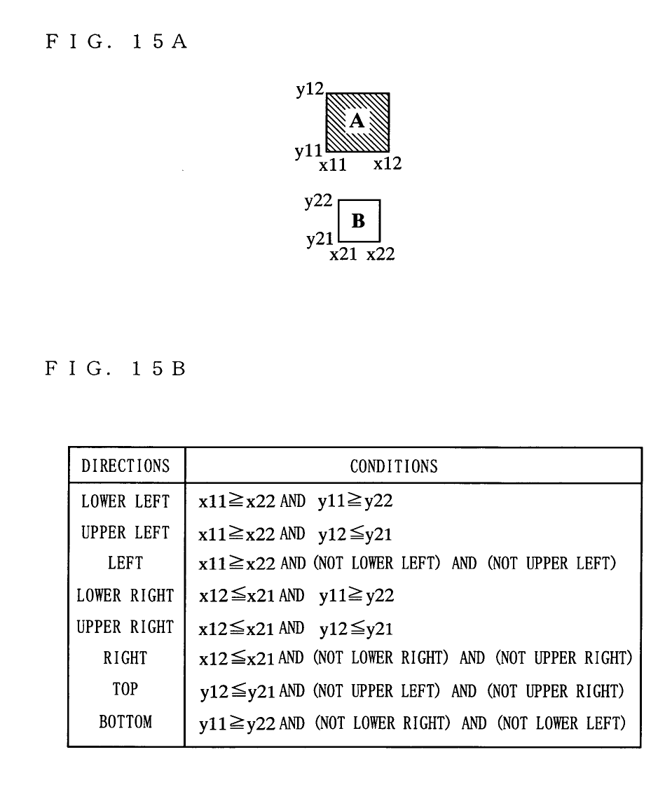

On the other hand, for example, when a placement of the elements is as illustrated in FIG. 14A, a horizontal graph is produced based on the layout data as illustrated in FIG. 14B. In this graph, when a depth-first search from left and a depth-first search from right are performed, a result of search from left (1400) and a result of search from right (1401) are obtained as illustrated in FIG. 14C. In this case, the symmetrical element pairs (A, C) and (E, F) each have different ordinal places in the search results. Therefore, the processing section 101 determines that the relative positional relationship does not satisfy the layout symmetry constraint.

In the foregoing description, it is assumed that the symmetry axis is parallel to the Y axis. Also, when the symmetry axis is parallel to the X axis, a relative positional relationship can be checked using the same procedure. When the symmetry axis is parallel to the X axis, by performing a depth-first search using a vertical graph, it is possible to check whether or not a relative positional relationship has a contradiction in the layout symmetry constraint. In this case, a procedure of the depth-first search is the same as that illustrated in the flowchart of FIG. 12.

As described above, also in the layout symmetry constraint checking method of the second embodiment, an error message is displayed in each step of the check process, thereby making it possible for the designer to easily confirm what error occurs, as with the layout symmetry constraint checking method of the first embodiment. Particularly, by using a horizontal graph and a vertical graph to detect an error that a relative positional relationship between elements does not satisfy the layout symmetry constraint, the designer can determine whether the detected error is a relatively trivial or serious, thereby making it possible to perform layout design efficiently.

### Third Embodiment

Next, a layout symmetry constraint checking method according to a third embodiment of the present invention will be described. The layout symmetry constraint checking method of the third embodiment is different from that of the first embodiment in the second check process. Therefore, only the second check process will be hereinafter described. In the third embodiment, as is different from the first embodiment, a relative positional relationship between elements is represented using eight directions, i.e., top, bottom, left, right, upper right, lower left, upper left, and lower right.

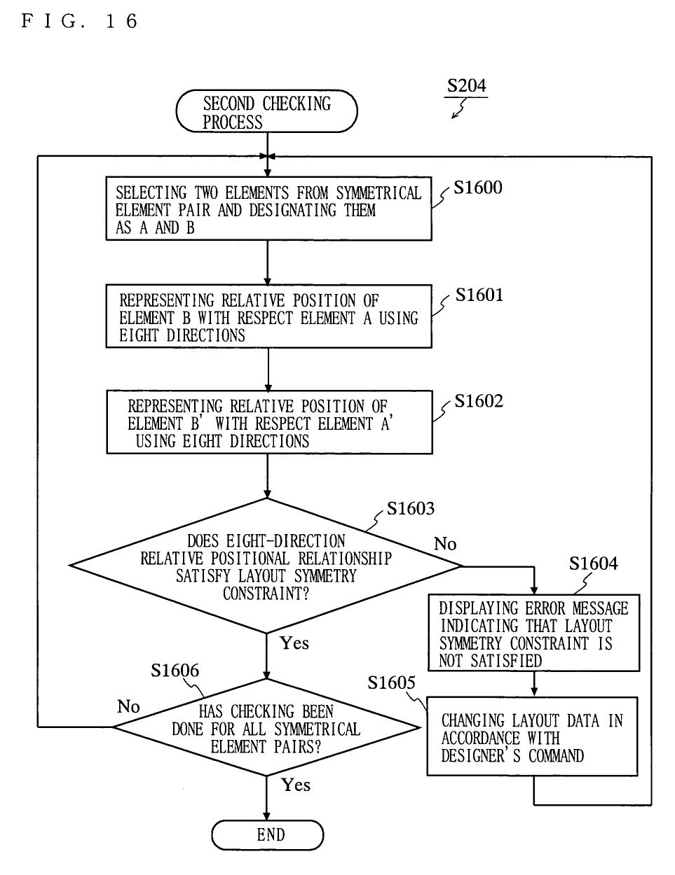

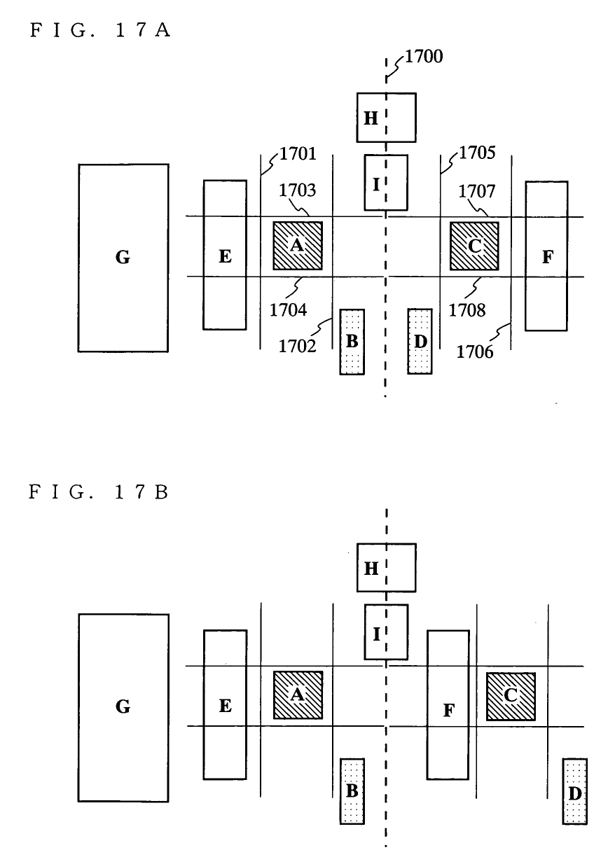

FIGS. 15A and FIG. 15B illustrate 8-direction conditions. FIG. 15A is a diagram illustrating ranges occupied by elements A and B. The x coordinate of the left side of the element A is represented by x11, and the x coordinate of the right side is represented by x12. The y coordinate of the bottom side of the element A is represented by y11, and the y coordinate of the top side is represented by y12. The range of the element B is also illustrated in FIG. 15A.

FIG. 15B is a table illustrating the eight directions and conditions thereof when a relative position of the element B with respect to the element A is represented using the eight directions. For example, it is assumed that, when x11>x22 and y11>y22, the element B is located to the lower left of the element A. Other relative positional relationships are similarly defined.

FIG. 16 is a flowchart illustrating details of a second check process of the third embodiment. In the second check process, as illustrated in FIG. 16, the processing section 101 selects any two symmetrical element pairs from layout data (step S1600). It is assumed that the two selected symmetrical element pairs are (A, A′) and (B, B′). Next, the processing section 101 represents a relative position of the element B with respect to the element A using the eight directions (step S1601). Next, the processing section 101 represents a relative position of the element B′ with respect to the element A′ using the eight directions (step S1602).

Next, the processing section 101 checks whether or not the eight-direction relative position of the element B with respect to the element A and the eight-direction relative position of the element B′ with respect to the element A′ satisfy a layout symmetry constraint, based on a condition described below (step S1603). The condition under which the eight-direction relative positional relationship between elements satisfies the layout symmetry constraint is that, when the symmetry axis is the Y axis, the relative position of the element B with respect to the element A and the relative position of the element B′ with respect to the element A′ are left-right symmetrical with respect to the symmetry axis. When the symmetry axis is the X axis, the relative position of the element B with respect to the element A and the relative position of the element B′ with respect to the element A′ are up-down symmetrical with respect to the symmetry axis.

When the eight-direction relative positional relationship between the elements does not satisfy the layout symmetry constraint, the processing section 101 detects an error and outputs a command to display an error message to the display section 106. Based on the command from the processing section 101, the display section 106 displays an error message indicating that the relative positional relationship does not satisfy the layout symmetry constraint (step S1604). When the designer changes the placement of the elements via the input section 105, the processing section 101 changes the layout data based on a process input by the designer (step S1605), and performs checking again (step S1600 to step S1603). When the above-described check process is performed for all symmetrical element pairs, the processing section 101 ends the second check process (Yes in step S1606).

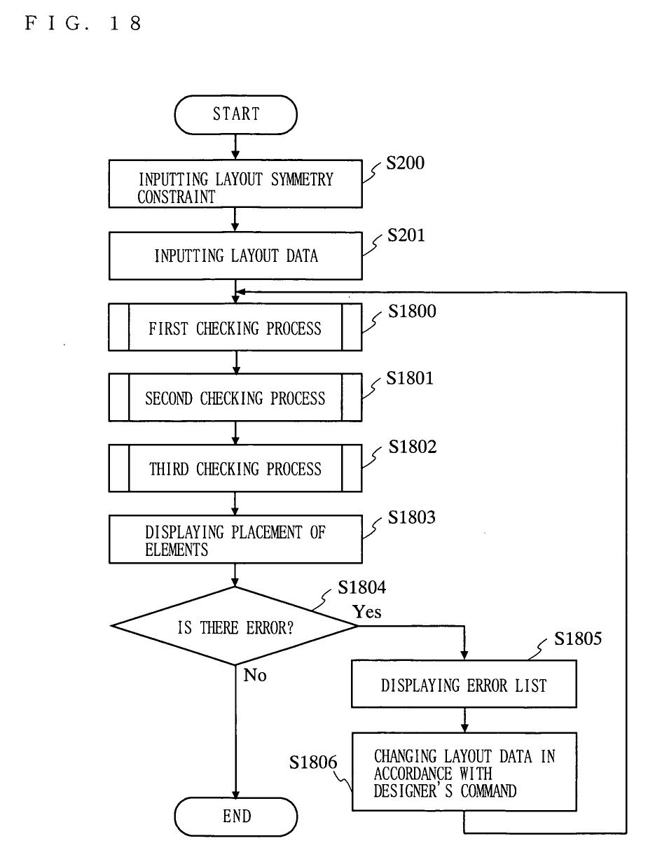

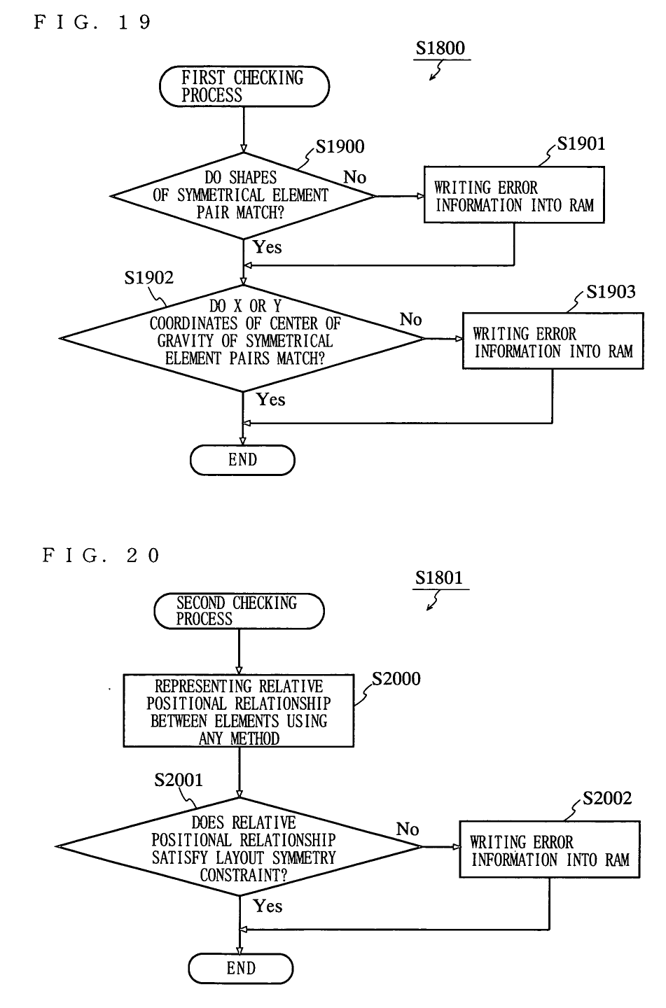

Hereinafter, a method of checking whether or not the eight-direction relative positional relationship between the elements satisfies the layout symmetry constraint will be described with reference to specific examples illustrated in FIG. 17A and FIG. 17B. FIG. 17A and FIG. 17B are diagrams illustrating layout data having a layout symmetry constraint γ=((A, C), (B, D), (E, F), H, I), which is similar to that of FIG. 3. Note that auxiliary lines 1701 to 1708 which pass across a symmetry axis 1700 and regions in eight directions are provided for illustrative purposes.

Referring to FIG. 17A, a description will be given of how a second check process is performed using an element A and an element C which constitute a symmetrical element pair. The element A and an element B, and the element C and an element D which constitute respective symmetrical element pairs with the element A and the element B, respectively, are checked. In FIG. 17A, the relative position of the element B with respect to the element A is lower right. Thereafter, the relative positional relationship between the elements which constitute respective symmetrical element pairs with the above-described respective elements are examined, i.e., the relative position of the element D with respect to the element C is lower left.

Further, the element A and an element E, and the element C and an element F which constitute respective symmetrical element pairs with the element A and the element E, respectively, are similarly checked. The relative position of the element E with respect to the element A is left, and the relative position of the element F with respect to the element C is right. According to these results, the relative positional relationship between the elements A, B, and E, and the elements C, D, and F which constitute respective symmetrical element pairs with the elements A, B, and E, respectively, satisfies the layout symmetry constraint.

On the other hand, the second check process is performed using the eight directions with respect to a placement of elements illustrated in FIG. 17B. The relative position of the element B with respect to the element A is lower right, and the relative position of the element D with respect to the element C is also lower right. The relative position of the element E with respect to the element A is left, and the relative position of the element F with respect to element C is also left. According to these results, the relative positional relationship between the elements A, B, and E, and the elements C, D, and F which constitute respective symmetrical element pairs with the elements A, B, and E, respectively, does not satisfy the layout symmetry constraint.

As described above, also in the layout symmetry constraint checking method of the third embodiment, an error message is displayed in each step of the check process, thereby making it possible to easily confirm what error occurs. Particularly, since an error that the relative positional relationship between elements does not satisfy the layout symmetry constraint is detected by using the eight directions, the designer can confirm whether the detected error is relatively trivial or serious, thereby making it possible to produce a layout design efficiently.

### Fourth Embodiment

Next, a layout symmetry constraint checking method according to a fourth embodiment of the present invention will be described. The layout symmetry constraint checking method of the fourth embodiment is also performed using a procedure substantially similar to that of the first embodiment. Therefore, hereinafter, a difference between the fourth embodiment and the first embodiment will be mainly described.

The layout symmetry constraint checking method of the fourth embodiment will be described with reference to FIG. 18. Input processes of a layout symmetry constraint (step S200) and layout data (step S201) are the same as those of the first embodiment and will not be explained.

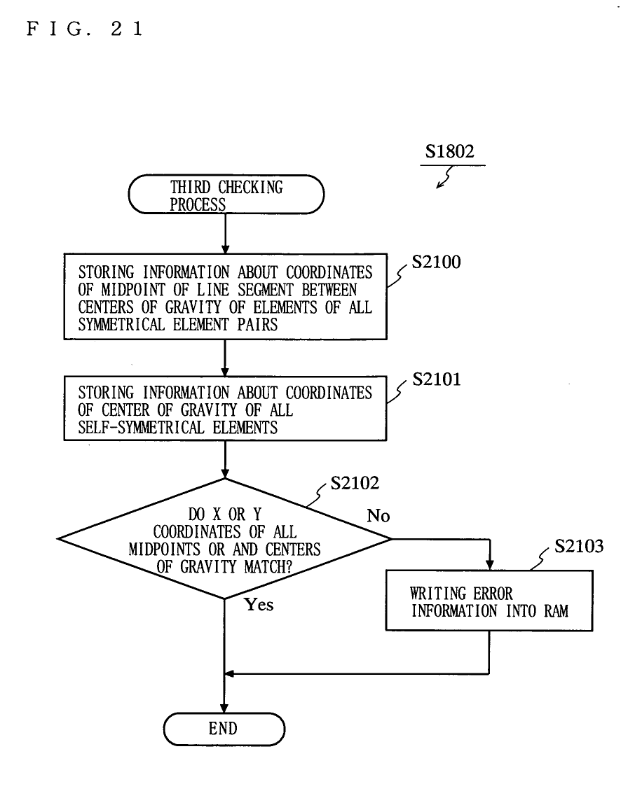

Next, the processing section 101 performs first to third check processes (step S1800 to step S1802). FIG. 19 to FIG. 21 are flowcharts illustrating details of the first to third check processes. As illustrated in FIG. 19 to FIG. 21, the first to third check processes of the third embodiment are similar to those of the first embodiment. Note that, in the second check process of the fourth embodiment, any of a sequence pair, a horizontal graph and a vertical graph, and eight directions may be used to represent a relative positional relationship between elements (step S2000).

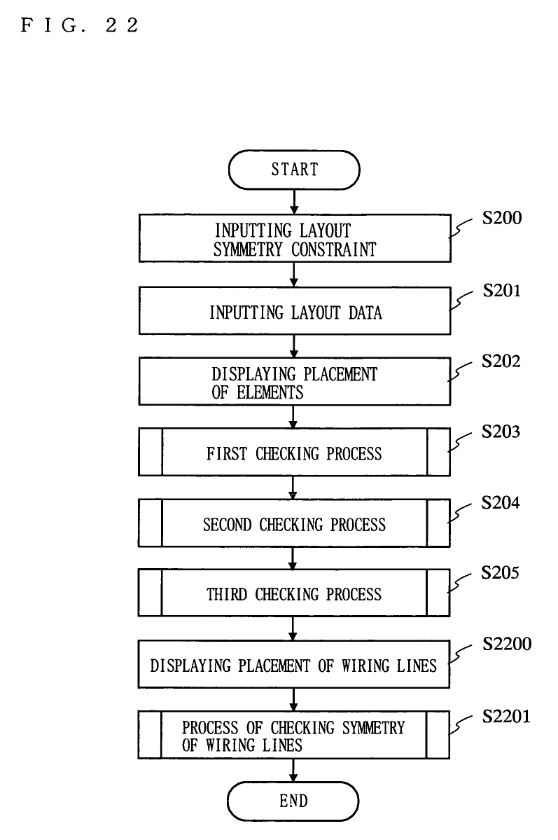

In the fourth embodiment, when an error is detected, the processing section 101 writes error information into the RAM 104 (step S1901 and S1903 in FIG. 19, step S2002 in FIG. 20, and step S2103 in FIG. 21). The other processes illustrated in FIG. 19 to FIG. 21 are the same as those of the first to third embodiments and will not be explained.

After the first, second, and third checks have been completed, the processing section 101 outputs a command to display a placement of elements to the display section 106, based on input layout data. Based on the command from the processing section 101, the display section 106 displays the placement of the elements (step S1803). Next, the processing section 101 references error information stored in the RAM 104 to determine whether or not there is an error (step S1804). When there is an error(s) (Yes in step S1804), the processing section 101 outputs a command to display information about all errors to the display section 106. Based on the command, the display section 106 displays a list of errors (step S1805). Next, when the designer selects an error to be resolved and changes the placement fo the elements via the input section 105, the processing section 101 changes the layout data based on an input process (step S1806).

Next, the processing section 101 performs the first to third check processes with respect to the changed layout data (step S1800 to step S1802). When an error is detected in each check process, the processing section 101 writes information about the detected error into the RAM 104. The reason why all the check processes are performed again is that, when the layout data is changed to resolve an error, there is a possibility that a new error occurs.

When the first to third check processes have been completed, the processing section 101 determines again whether or not there is an error(s) (step S1804). If there is an error, the processing section 101 outputs a command to the display section 106. Based on the command, the display section 106 displays a list of errors (step S1805). The processing section 101 performs the above-described procedure from step S1800 to step S1806 until all errors are resolved. When all the errors are resolved (No in step S1804), the processing section 101 ends checking of the layout symmetry constraint.

As described above, according to the layout symmetry constraint checking method of the fourth embodiment, a list of errors occurring in the check processes is displayed, whereby the designer can easily conform what error occurs. Further, by the processing section 101 performing the first to third check processes again after the placement of elements is changed by the designer, it is possible to detect an error which newly occurs due to a change in the placement of the elements.

### Fifth Embodiment

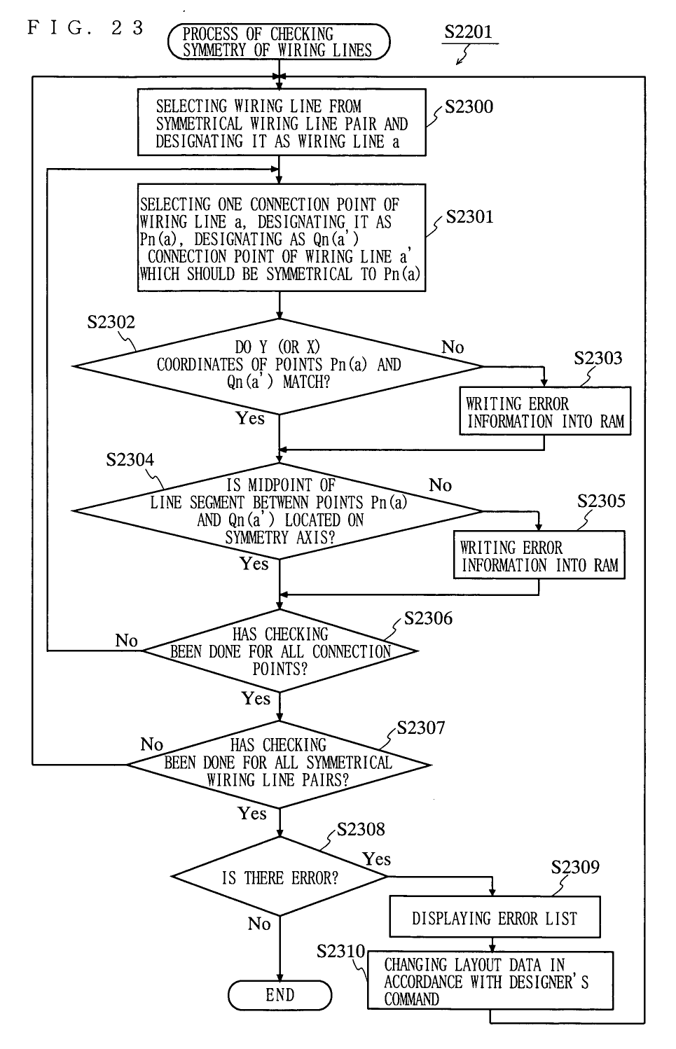

Next, a layout symmetry constraint checking method according to a fifth embodiment of the present invention will be described. FIG. 22 is a flowchart illustrating the layout symmetry constraint checking method of the fifth embodiment. The flowchart of FIG. 22 is obtained by adding step S2200 and step S2201 to the flowchart of FIG. 2.

The layout symmetry constraint checking method of the fifth embodiment is performed in accordance with the flowchart of FIG. 22. In the fifth embodiment, the processing section 101 receives a layout symmetry constraint and layout data. Note that, in the fifth embodiment, the layout symmetry constraint and the layout data include information about wiring lines which should be symmetrical with respect to a symmetry axis (hereinafter referred to as a symmetrical wiring line pair) in addition to information about elements.

Next, the display section 106 displays a placement of elements (step S202), and the processing section 101 performs the first to third check processes (step S203 to step S204) in a manner similar to that of the first, second, or third embodiment. With these check processes, the elements are placed to satisfy the layout symmetry constraint.

After the layout symmetry constraint for the elements has been checked, the processing section 101 outputs a command to display a placement of wiring lines to the display section 106, based on the input layout data. Based on the command, the display section 106 displays the placement of the wiring lines (step S2200). Next, the symmetry of the wiring lines is checked.

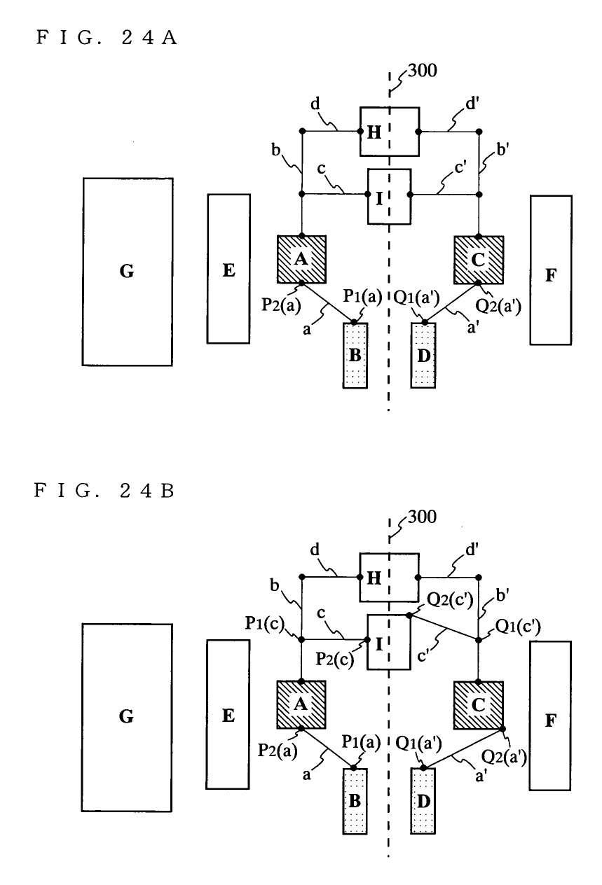

FIG. 23 is a flowchart illustrating details of a process of checking the symmetry of the wiring lines. As illustrated in FIG. 23, the processing section 101 selects one wiring line from a symmetrical wiring line pair included in the layout symmetry constraint (step S2300). The wiring line (hereinafter referred to as a wiring line a) is connected to elements or other wiring lines at a plurality of points (hereinafter referred to as connection points). The processing section 101 selects one connection point (hereinafter referred to as Pn(a)) from the plurality of connection points of the wiring line a and a connection point (hereinafter referred to as Qn(a′)) which should be symmetrical to the connection point Pn(a) from a plurality of connection points of a wiring line a′ which constitutes a symmetrical wiring line pair with the wiring line a (step S2301).

The symmetry of the wiring lines is checked with respect to a symmetry axis which has been determined from the layout symmetry constraint for elements. When the symmetry axis is parallel to the Y axis, the processing section 101 checks whether or not the Y coordinates of the points Pn(a) and Qn(a′) match (step S2302). When the symmetry axis is parallel to the X axis, the processing section 101 checks whether or not the X coordinates of the points Pn(a) and Qn(a′) match. In step S2302, when it is determined that the Y or X coordinates of these points do not match, the processing section 101 writes error information into the RAM 104 (step S2303).

Next, the processing section 101 checks whether or not the midpoint of a line segment between the points Pn (a) and Qn(a′) is located on the symmetry axis (step S2304). When the midpoint of the line segment between the points Pn(a) and Qn(a′) is not located on the symmetry axis, the processing section 101 writes error information to the RAM 104 (step S2305). Step S2301 to step S2305 are repeatedly performed for all of the connection points of the wiring line a and the wiring line a′ (step S2306).

After the above-described procedure has been performed for all symmetrical wiring line pairs (Yes in step S2307), the processing section 101 determines whether or not there is error information in the RAM 104. When there is an error(s) (Yes in step S2308), a command to display a list of errors is output to the display section 106. Based on the command, the display section 106 displays the error list (step S2309). When the designer changes the placement of the wiring lines via the input section 105, the processing section 101 changes the layout data based on a process input by the designer (step S2310), and performs checking again (step S2300 to step S2307). When all errors are resolved (No in step S2308), the processing section 101 ends checking of the symmetry of the wiring line.

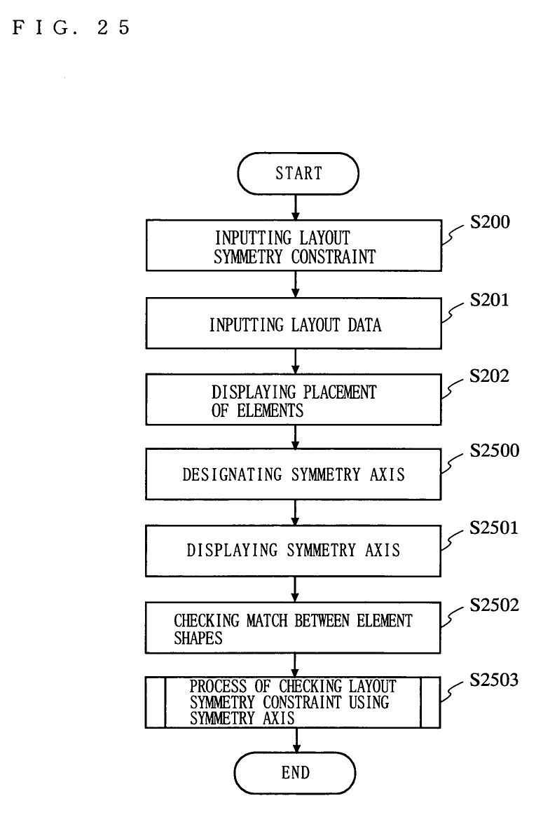

Hereinafter, the process of checking the symmetry of the wiring lines will be described with reference to specific examples illustrated in FIG. 24A and FIG. 24B. It is assumed that, after checking of the layout symmetry constraint for elements has been ended, the elements are placed as illustrated in FIG. 3. Based on the symmetry of the elements, a symmetry axis 300 is determined. Next, in step S2200, a placement of wiring lines is displayed based on the layout data. It is assume that the wiring lines are placed as illustrated in FIG. 24A.

Next, symmetry is checked for the wiring lines of FIG. 24A in accordance with the flowchart of FIG. 23. It is assumed that, in step S2300, a wiring line a and a wiring line a′ which constitute a symmetrical wiring line pair is selected from symmetrical wiring line pairs. Next, in step S2301, the processing section 101 checks whether or not a connection point P1(a) between the wiring line a and the element B and a connection point Q1(a′) between the wiring line a′ and the element D have the same Y coordinate. Since the Y coordinates of the points P1(a) and Q1(a′) match, it is determined that there is not an error.

Next, the processing section 101 checks whether or not the midpoint of a line segment between the point P1(a) and the point Q1(a′) is located on the symmetry axis. Since the midpoint of the line segment between the point P1(a) and the point Q1(a′) is located on the symmetry axis, it is determined that there is not an error. Next, the processing section 101 similarly checks a connection point P2(a) between the wiring line a and the element A and a connection point Q2(a′) between the wiring line a′ and the element C. Since these points have symmetry, it is determined that there is not an error. Therefore, the wiring line a and the wiring line a′ which constitute a symmetrical wiring line pair are symmetrical with respect to the symmetry axis 300.

Similarly, it can be seen that wiring lines b and b′, wiring lines c and c′, and wiring lines d and d′, are symmetrical with respect to the symmetry axis 300. Therefore, in this case, the processing section 101 determines that there is not an error, so that an error list is not displayed on the display section 106. Therefore, the designer can recognize that the wiring lines a to d and the wiring lines a′ to d′ satisfy the layout symmetry constraint.

On the other hand, in step S2200, the wiring lines are assumed to be placed as illustrated in FIG. 24B. Symmetry is checked for the wiring lines. In this case, concerning the wiring line a and the wiring line a′, an error that the midpoint of a line segment between the point P2(a) and the point Q2(a′) is not located on the symmetry axis 300 is detected in step S2304, and the processing section 101 writes error information into the RAM 104. Concerning the wiring line c and the wiring line c′, an error that the Y coordinates of the point P2(c) and the point Q2(c′) do not match is detected in step S2302, and the processing section 101 writes error information into the RAM 104. Concerning the wiring line b and the wiring line b′, and the wiring line d and the wiring line d′, it is determined that there is not an error.

Therefore, in step S2308, the processing section 101 determines that error information is stored in the RAM 104, and outputs a command to display an error message to the display section 106. The display section 106 displays an error message indicating that, concerning the wiring line a and the wiring line a′, the midpoint of the line segment between the point P2(a) and the point Q2(a′) is not located on the symmetry axis 300, and concerning the wiring line c and the wiring line c′, the Y coordinates of the point P2(c) and the point Q2(c′) do not match.

As described above, by using the layout symmetry constraint checking method of the fifth embodiment, a layout symmetry constraint can be checked for a symmetrical wiring line pair which should be symmetrical. By specifying a wiring line which causes an error or displaying what error prevents satisfaction of a layout symmetry constraint, layout design can be efficiently performed.

In the layout symmetry constraint checking method of the fifth embodiment, the method of checking a layout symmetry constraint for elements is similar to that of the first embodiment. Alternatively, in the layout symmetry constraint checking method of the fifth embodiment, the method of checking a layout symmetry constraint for elements is similar to that of the second, third, or fourth embodiment.

### Sixth Embodiment

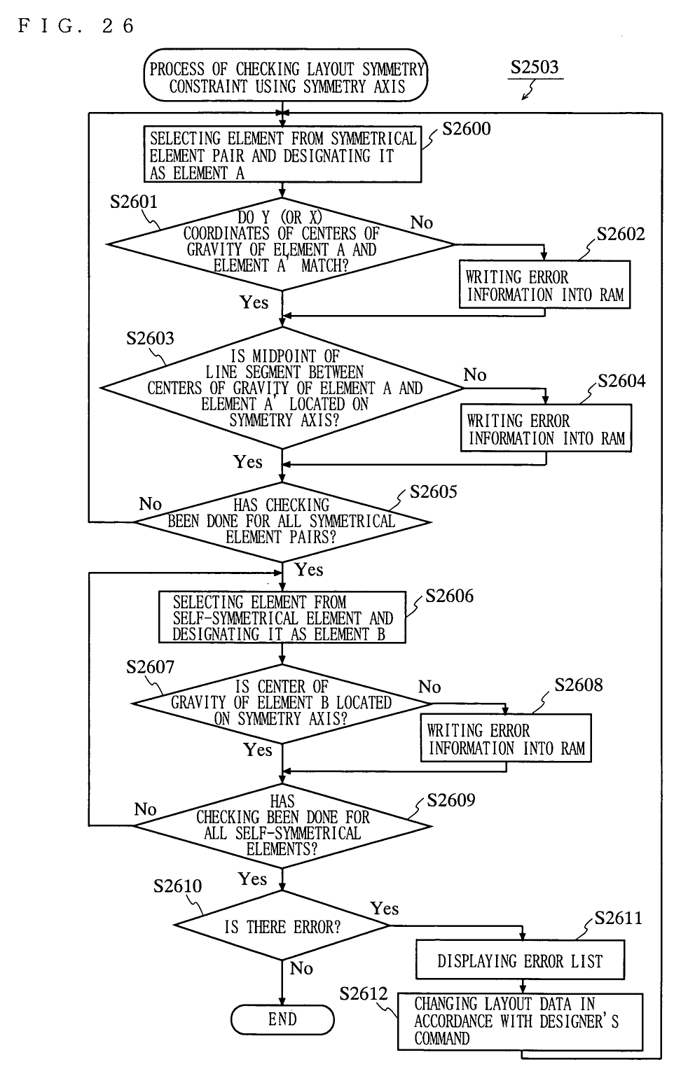

Next, a procedure of a layout symmetry constraint checking method according to a sixth embodiment of the present invention will be described with respect to FIG. 25. The layout symmetry constraint checking method of the sixth embodiment is characterized in that a layout symmetry constraint is checked while a symmetry axis which is not displayed in conventional layout symmetry constraint checking methods is displayed on a screen. The sixth embodiment is similar to the first embodiment in many respects, and therefore, a difference between the sixth embodiment and the first embodiment will be mainly described below.

Inputting of a layout symmetry constraint and layout data to the processing section 101 (step S200 and step S201) is the same as that of the first embodiment and will not be explained. The display section 106 displays a placement of elements based on the layout data input to the processing section 101 (step S202).

Next, when receiving a command to designate a symmetry axis via the input section 105 (step S2500), the processing section 101 outputs a command to display the symmetry axis to the display section 106 based on input information about the symmetry axis. Based on the command, the display section 106 displays the symmetry axis (step S2501).

Next, the processing section 101 checks whether or not elements constituting a symmetrical element pair have the same shape (step S2502). It is here assumed that the processing section 101 checks a match between the shapes of elements in a manner similar to the first check process of the first embodiment. The processing section 101 checks the layout symmetry constraint using the symmetry axis (step S2503).

FIG. 26 is a flowchart illustrating details of the process of checking the layout symmetry constraint using the symmetry axis. Hereinafter, the process of checking the layout symmetry constraint using the symmetry axis will be described with reference to the flowchart of FIG. 26. The processing section 101 selects one element to be checked about symmetry from a symmetrical element pair included in the layout symmetry constraint (step S2600).

Next, the processing section 101 checks whether or not the element (hereinafter referred to as an element A), and an element A′ which constitutes a symmetrical element pair with the element A, have the same Y (or X) coordinate of the center of gravity (step S2601). In this case, when symmetry axis is parallel to the Y axis, the processing section 101 checks a match between the Y coordinates of the centers of gravity. When the symmetry axis is parallel to the X axis, the processing section 101 checks a match between the X coordinates of the centers of gravity. In step S2601, when the Y (or X) coordinates of the centers of gravity of the elements do not match, the processing section 101 writes error information into the RAM 104 (step S2602).

Next, the processing section 101 checks whether or not the midpoint of a line segment between the centers of gravity of the element A and the element A′ is located on the symmetry axis (step S2603). When the midpoint of the line segment between the centers of gravity of the element A and the element A′ is not located on the symmetry axis, the processing section 101 writes error information into the RAM 104 (step S2604). The processes of step S2600 to step S2604 are repeatedly performed for all symmetrical element pairs included in the layout symmetry constraint (step S2605).

After the layout symmetry constraint has been checked for all of the symmetrical element pairs included in the layout symmetry constraint (Yes in step S2605), the layout symmetry constraint is checked for all self-symmetrical elements included in the layout symmetry constraint.

The processing section 101 selects one element to be checked for symmetry from the self-symmetrical elements included in the layout symmetry constraint (step S2606). Next, the processing section 101 checks whether or not the center of gravity of the element (hereinafter referred to as an element B) is located on the symmetry axis (step S2607). When the center of gravity of the element B is not located on the symmetry axis, the processing section 101 writes error information into the RAM 104 (step S2608). The processes of step S2606 to step S2608 are repeatedly performed for all of the self-symmetrical elements included in the layout symmetry constraint (step S2609).

After the above-described steps have been performed for all of the elements included in the layout symmetry constraint (Yes in step S2609), the processing section 101 determines whether or not there is error information in the RAM 104 (step S2610). When there is error information, the processing section 101 outputs a command to display a list of errors to the display section 106. Based on the command, the display section 106 displays the error list (step S2611). When the designer changes the placement of the elements via the input section 105, the processing section 101 changes the layout data based on a process input by the designer (step S2612), and performs checking again (step S2600 to step S2610). When all errors are resolved (No in step S2610), the processing section 101 ends the process of checking the layout symmetry constraint using the symmetry axis.

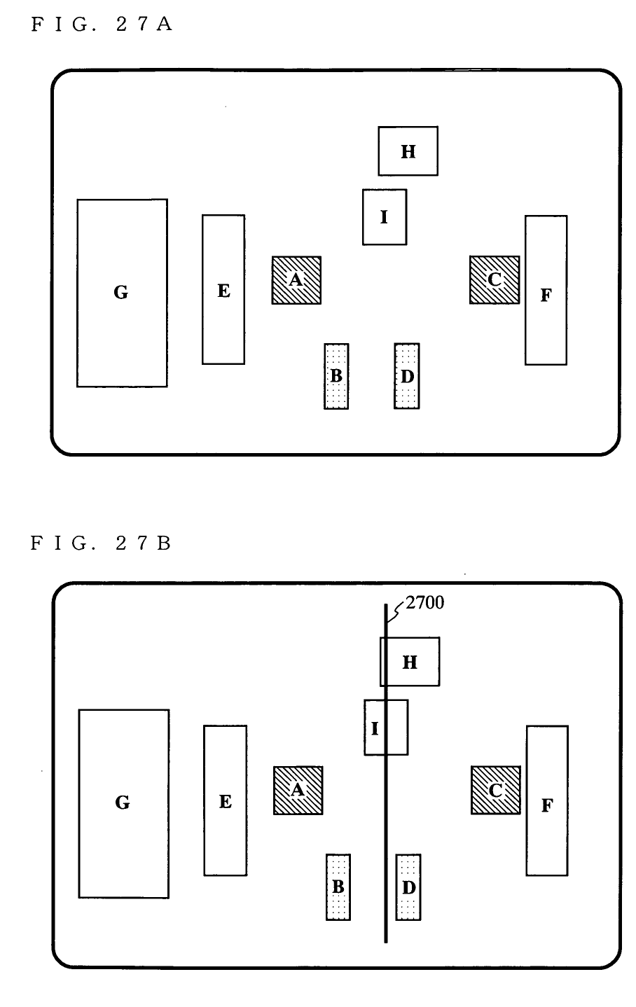

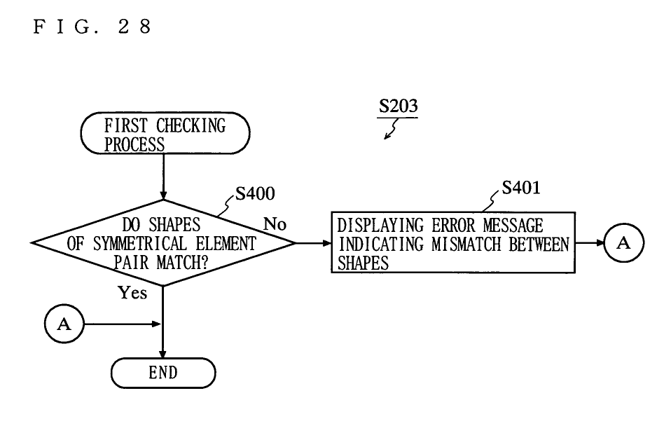

In conventional layout design, a symmetry axis is not displayed on a screen as illustrated in FIG. 27A. Therefore, the designer places elements while imagining a symmetry axis. Assuming that the layout symmetry constraint for the placement of the elements of FIG. 27A is γ=((A, C), (B, D), (E, F), H, I), a plurality of errors occur against the layout symmetry constraint. However, since a symmetry axis is not displayed, it is considerably difficult to specify what element is correctly placed.

In contrast, in the layout symmetry constraint checking method of the sixth embodiment, a symmetry axis is designated by the designer and the designated symmetry axis 2700 is displayed as illustrated in FIG. 27B. By designating the symmetry axis, it is specified which symmetrical element pair or self-symmetrical element does not satisfy the layout symmetry constraint. Further, the designer is provided with a display which allows the designer to easily understand the placement of which element does not satisfy symmetry. Therefore, by using the layout symmetry constraint checking method of the sixth embodiment, the processing speed of checking the layout symmetry constraint is improved, so that the efficiency of layout design is increased.

In the sixth embodiment, the layout symmetry constraint is checked without using the relative positional relationship between elements. Alternatively, by performing checking of the relative positional relationship between elements using a sequence pair, horizontal and vertical graphs, or using eight directions in combination with the checking method of the sixth embodiment using a symmetry axis, the layout symmetry constraint can be more efficiently checked, particularly when the number of elements is large or a circuit is complicated.

### Seventh Embodiment

Next, a layout symmetry constraint checking method according to a seventh embodiment of the present invention will be described. The layout symmetry constraint checking method of the seventh embodiment has a basic structure similar to that of the first embodiment. Therefore, a difference between the seventh embodiment and the first embodiment will be mainly described with reference to FIGS. 1 and 2 of the first embodiment.

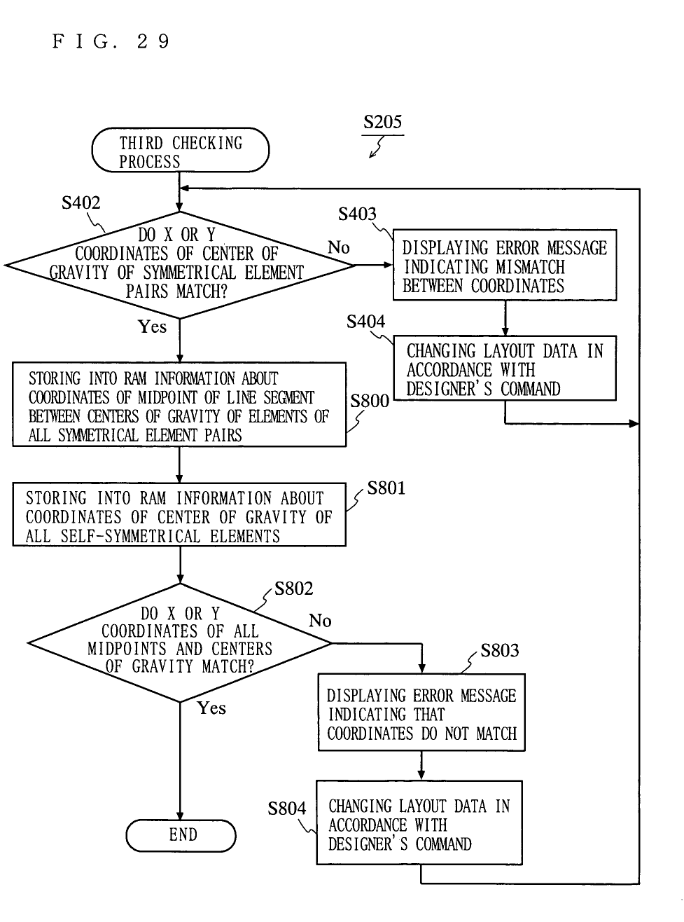

FIG. 28 is a flowchart illustrating a first checking procedure in the layout symmetry constraint checking method of the seventh embodiment of the present invention. FIG. 29 is a flowchart illustrating a third checking procedure in the layout symmetry constraint checking method of the seventh embodiment of the present invention.

The seventh embodiment is different from the first embodiment in that a portion of steps included in the first check process (steps S402 to S404 of FIG. 4) of the first embodiment are performed in the third check process. More specifically, the first check process of FIG. 28 includes steps S400 and S401. In the first check process, the processing section 101 determines whether or not shapes of a symmetrical element pair match. The third check process of FIG. 29 includes steps S402 to S404 in addition to step S800 to S804 of FIG. 8. In the third check process, the processing section 101 checks whether or not the X or Y coordinates of the centers of gravity of elements constituting a symmetrical element pair match (step S402). When the X or Y coordinates of the symmetrical element pair do not match, the processing section 101 detects an error and outputs a command to display an error message to the display section 106. Based on the command from the processing section 101, the display section 106 displays an error message indicating that the X or Y coordinates of the centers of gravity of the symmetrical element pair do not match (step S403) Based on the error message, the designer changes a placement of the elements via the input section 105. The processing section 101 changes the layout data in accordance with a command from the designer (step S404) Thereafter, the processing section 101 returns to step S402, and performs the above-described process.

In step S402, when the X or Y coordinates of the symmetrical element pair match, the processing section 101 goes to step S800 and performs subsequent processes.

Note that the details of the other steps (S400 and S401, step S800 to S804) of FIG. 28 and FIG. 29 are the same as those of the respective corresponding steps of FIG. 4 and FIG. 8 of the first embodiment and will not be explained.

By performing the first to third check processes of the seventh embodiment, all of the check processes of the first embodiment are performed. Therefore, the layout symmetry constraint checking method of the seventh embodiment can have the same effect as that of the first embodiment.

### Eighth Embodiment

Next, a layout symmetry constraint checking method according to an eighth embodiment of the present invention will be described.

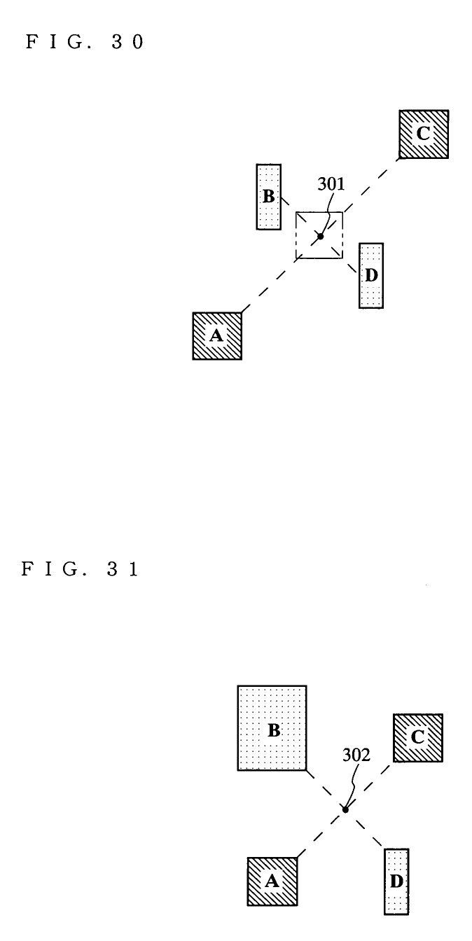

FIG. 30 is a diagram illustrating an exemplary placement of elements for which a layout symmetry constraint is checked using the layout symmetry constraint checking method of the eighth embodiment of the present invention. The layout shown in FIG. 30 includes symmetrical element pairs (A, C) and (B, D) which are placed point-symmetrical with respect to a symmetry center 301.

The layout symmetry constraint checking method of the eighth embodiment comprises: a layout symmetry constraint inputting step of inputting a layout symmetry constraint including information about a symmetrical element pair which should be placed point-symmetrical with respect to the symmetry center 301; a layout data inputting step of inputting layout data including information about shapes of elements and information about a placement of the elements; a first checking step of checking whether or not the shapes of elements of a symmetrical element pair match, based on the shape information included in the layout data; and a second checking step of checking whether or not a relative positional relationship of a symmetrical element pair satisfies a layout symmetry constraint, based on the placement information included in the layout data.

Note that the layout symmetry constraint inputting step, the layout data inputting step, and the first checking step are the same as those of the first embodiment, and will not be explained. Instead, FIG. 1, FIG. 2, and FIG. 4 will be referenced.

Also, the second checking step is similar to that of the third embodiment. Therefore, a difference between the eighth embodiment and the third embodiment will be mainly described with reference to FIG. 16. The second check process of the eighth embodiment is different from that of the third embodiment in the details of step S1603 of FIG. 16.

The processing section 101 selects two symmetrical element pair (A, A′) and (B, B′) in step S1601. Next, the processing section 101 represents a relative position of the element B with respect to the element A and a relative position of the element B′ with respect to the element A′ using eight directions, based on the conditions of FIG. 15A and FIG. 15B (step S1602). The processing section 101 checks whether or not the relative positions represented in step S1602 satisfy a predetermined condition (step S1603). In the eighth embodiment, the predetermined condition means that, when the relative position of the element B with respect to the element A is reversed left to right and up to down, the reversed relative position of the element B with respect to the element A matches the relative position of the element B′ with respect to the element A′. Hereinafter, the processing section 101 performs subsequent processes similar to those of the third embodiment.

Hereinafter, a method of checking whether or not a relative positional relationship between elements satisfies a layout symmetry constraint, using eight directions, will be described with reference to the specific example of FIG. 30. As illustrated in FIG. 30, the elements A and C are a symmetrical element pair which should be placed point-symmetrical with respect to a symmetry center 301, and the element B and the element D are a symmetrical element pair which should be placed point-symmetrical with respect to a symmetry center 301. A layout symmetry constraint for the placement of the elements of FIG. 30 is represented by γ=((A, C), (B, D)) for the sake of convenience.

In the example of FIG. 30, the processing section 101 selects two pairs of elements (A, C) and (B, D). Next, the processing section 101 represents the relative position of the element B with respect to the element A and the relative position of the element D with respect to the element C using eight directions. In the example, the relative position of the element B with respect to the element A is upper right, and the relative position of the element D with respect to the element C is lower left. A relative position obtained by reversing the relative position of the element B with respect to the element A (upper right) matches the relative position of the element D with respect to the element C (lower left). Therefore, the processing section 101 determines that the elements A to D satisfy the above-described layout symmetry constraint y.

FIG. 31 is a diagram illustrating an exemplary placement of elements in which an error occurs in the first checking process of the layout symmetry constraint checking method of the eighth embodiment of the present invention. In the example of FIG. 31, whereas the element A and the element C have the same shape, the element B and the element D have different shapes. When such layout data is input, by the process of the above-described first checking step it is found that there is an error in the layout data. More specifically, the processing section 101 determines that the shapes of a symmetrical element pair do not match, in step S400 of FIG. 4.

As described above, according to the layout symmetry constraint checking method of the eighth embodiment, it is possible to check whether or not elements included in layout data are placed point-symmetrical with respect to a symmetry center.

Note that the layout symmetry constraint checking method of the eighth embodiment may further comprise a third checking step of checking whether or not a geometric placement of each element satisfies a layout symmetry constraint, based on element placement information included in the layout data. For example, referring to FIG. 30, in the third check process, the processing section 101 checks whether or not the midpoint of a line segment (dashed line) between the centers of gravity of the symmetrical element pair (A, C) matches the symmetry center 301. Also, the processing section 101 checks whether or not the midpoint of a line segment (dashed line) between the centers of gravity of the symmetrical element pair (B, D) matches the symmetry center 301. The processing section 101 performs a similar process for all symmetrical element pairs included in the layout data. When the midpoint of a line segment between the centers of gravity matches the symmetry center 301 for all of the symmetrical element pairs, the processing section 101 may determine that a geometric placement of all of the symmetrical element pairs included in the layout data satisfies the layout symmetry constraint.

In this variation, the layout symmetry constraint may further include information about a self-symmetrical element which should be placed point-symmetrical with respect to the symmetry center. In this case, in the third check process, the processing section 101 may check whether or not the self-symmetrical element included in the layout data is placed point-symmetrical with respect to the symmetry center. More specifically, in the example of FIG. 30, the processing section 101 may check whether or not the center of gravity of a self-symmetrical element indicated using a dashed double-dotted line matches the symmetry center 301.

### Ninth Embodiment

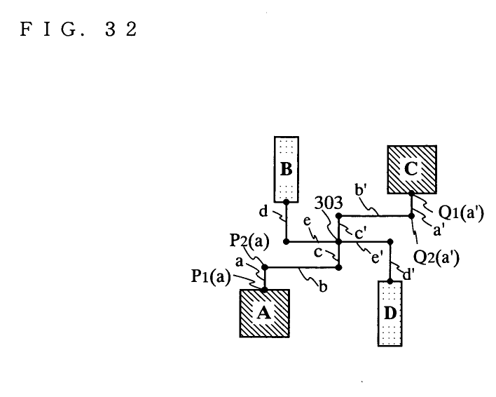

FIG. 32 is a diagram illustrating a placement of wiring lines for which a layout symmetry constraint is checked using a layout symmetry constraint checking method according to a ninth embodiment of the present invention. The layout shown in FIG. 32 includes elements A to D and wiring lines a to e and a′ to e′. The layout symmetry constraint checking method of the ninth embodiment is a method of checking whether or not a placement of the elements A to D satisfies a layout symmetry constraint and the wiring lines a to e and a′ to e′ each satisfy the layout symmetry constraint.

The layout symmetry constraint checking method of the ninth embodiment has a basic structure similar to that of the fifth embodiment. Therefore, a difference between the ninth embodiment and the fifth embodiment will be hereinafter mainly described with reference to FIG. 1 and FIG. 22. Note that the checking method of the eighth embodiment is applied to check whether or not each of symmetrical element pairs (A, C) and (B, D) is placed point-symmetrical with respect to a symmetry center 303 in steps S200 to S205 in FIG. 22.

In the ninth embodiment, layout data includes information about a plurality of wiring lines which are connected to respective elements, and information about a symmetrical wiring line pair which should be placed symmetrical with respect to a symmetry center.

The processing section 101 causes the display section 106 to display the wiring lines a toe and a′ to e′ included in the layout data in step S2200 of FIG. 22. Thereafter, the processing section 101 checks symmetry of the wiring lines a to e and a′ to e′.

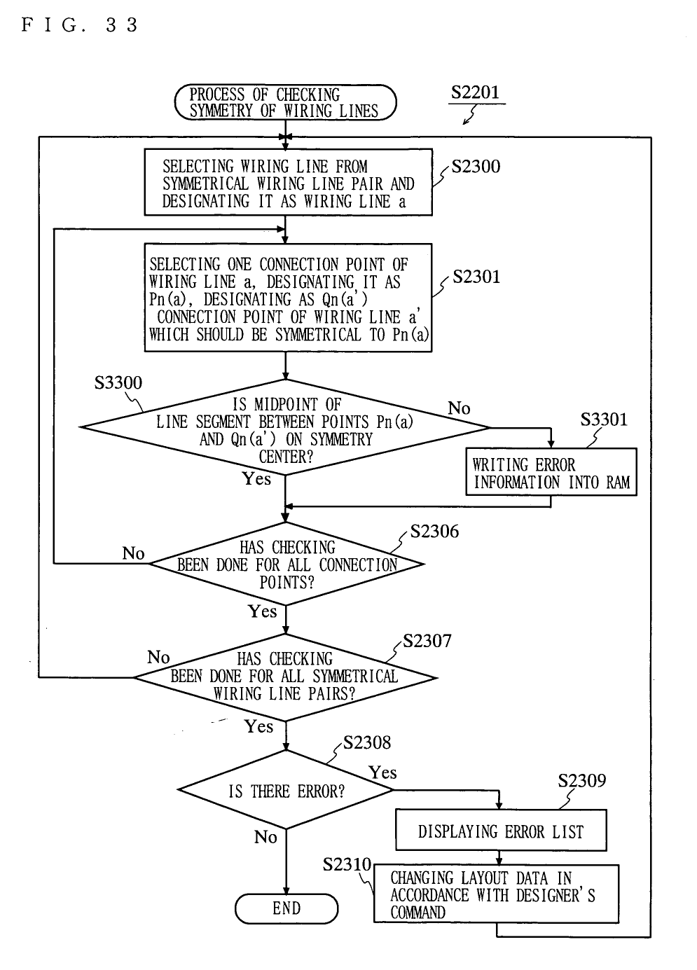

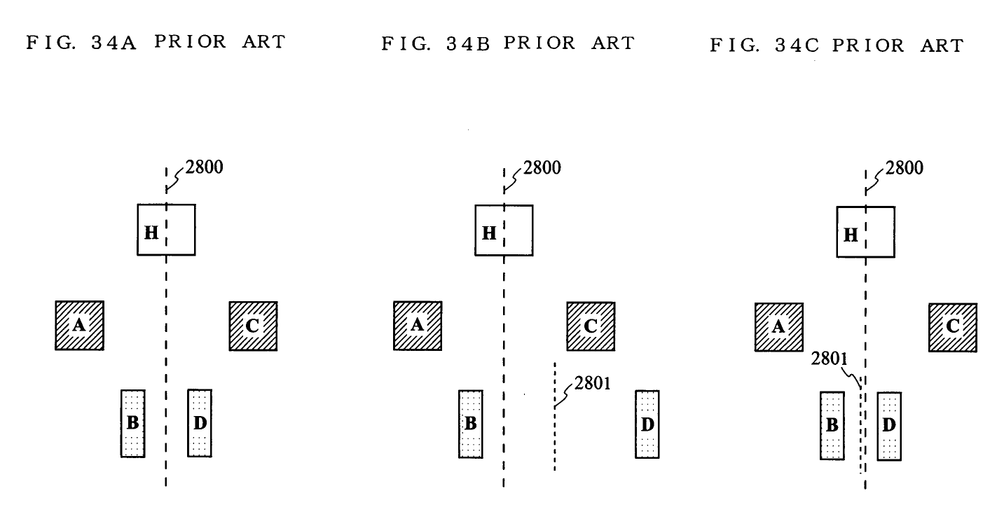

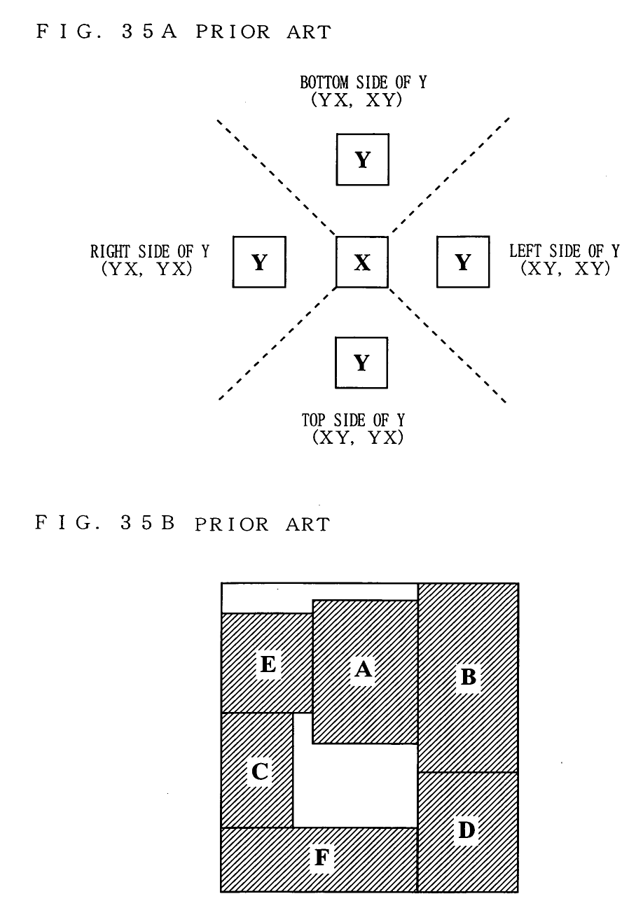

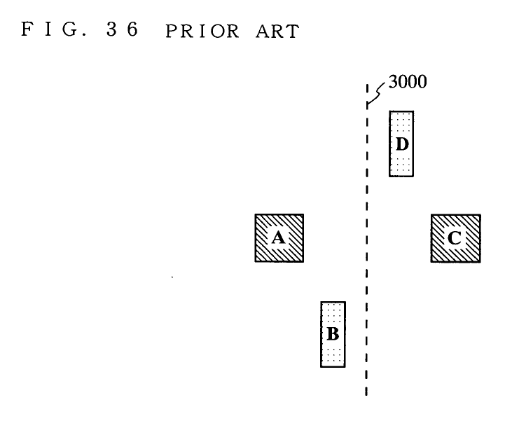

FIG. 33 is a flowchart illustrating a procedure of checking the symmetry of wiring lines using the layout symmetry constraint checking method of the ninth embodiment of the present invention. The flowchart of FIG. 33 is substantially similar to that of FIG. 23. Note that, in the ninth embodiment, steps S3300 and S3301 are included instead of steps S2302 to S2304 of FIG. 23.

Following step S2301 of FIG. 33, the processing section 101 checks whether or not the midpoint of a line segment between a point Pn(a) and a point Qn(a′) matches the symmetry center (step S3300). When the midpoint of the line segment between the point Pn(a) and Qn(a′) does not match the symmetry center, the processing section 101 writes error information into the RAM 104 (step S3301). Thereafter, the processing section 101 performs the process of step S2306 of FIG. 33. Also in the above-described step S3300, when the midpoint of the line segment between the point Pn(a) and Qn(a′) matches the symmetry center, the processing section 101 performs the process of step S2306 of FIG. 33.

Hereinafter, a method of checking symmetry of wiring lines a to e and a′ to e′ will be described with reference to FIG. 32. Layout data includes a plurality of wiring lines a to e and a′ to e′.

The processing section 101 selects a symmetrical wiring line pair (a, a′) which should be placed point-symmetrical with respect to the symmetry center 303. Next, the processing section 101 selects the connection point P1(a) of the one wiring line a, and the connection point Q1(a′) of the other wiring line a′. Next, the processing section 101 checks whether or not the midpoint of the line segment between the point P1(a) and the point Q1(a′) matches the symmetry center 303. More specifically, a two-dimensional placement of elements included in the layout data may be represented by the Cartesian coordinate system, and it may be determined whether or not the calculated coordinates of the midpoint matches the coordinates of the symmetry center 303. When the midpoint between the points P1(a) and Q1(a′) matches the symmetry center, the processing section 101 performs a similar check process using other connection points P2(a) and Q2(a′) of the symmetrical wiring line pair (a, a′). When the points P1(a) and Q1(a′) are point-symmetrical with respect to the symmetry center 303, and the points P2(a) and Q2(a′) are point-symmetrical with respect to the symmetry center 303, the processing section 101 may determine that the symmetrical wiring line pair (a, a′) satisfies the layout symmetry constraint.

As described above, according to the layout symmetry constraint checking method of the ninth embodiment, when a pair of wiring lines need to be point-symmetrical with respect to a symmetry center, the symmetry of the wiring line pair as well as the symmetry of elements can be checked.

Note that, in the layout symmetry constraint checking method of each of the above-described embodiments, for the sake of simplicity, the symmetry of a placement of elements is checked using the centers of gravity of the elements included in layout data as references. However, instead of the center of gravity of an element, a representative point of the element may be used as a reference. In this case, the present invention can be similarly applied. For example, the representative point of an element may be a vertex of the element other than the center of gravity of the element. When an element is a cell, the representative point of the element may be the origin of the cell.

In the present invention, a center graphic is a concept including at least a symmetry axis and a symmetry center.

The layout symmetry constraint checking method of each of the above-described embodiments may not necessarily comprise all of the first to third check processes. For example, the layout symmetry constraint checking method may comprise one of a process of checking whether or not a relative positional relationship between elements included layout data satisfies a layout symmetry constraint and a process of checking whether or not a geometric placement of the elements included in the layout data satisfies symmetry defined in the layout symmetry constraint, in addition to a process of checking whether or not the shapes of a symmetrical element pair match. Also in this case, the symmetry of layout data can be checked.

In the above-described eighth and ninth embodiments, the layout symmetry constraint checking method may further comprise a step of designating a symmetry center defined in a layout symmetry constraint and a step of displaying the designated symmetry center. According to such a layout symmetry constraint checking method, an effect similar to that of the sixth embodiment is obtained. Specifically, the designer can easily determine, by visual inspection, whether or not a symmetrical element pair or a symmetrical wiring line pair satisfies symmetry with respect to a symmetry center.

Further, it is possible to provide the following variation for each of the above-described embodiments. In each of the above-described embodiments, it is checked whether or not the shapes of elements match. The shapes of elements may not need to match exactly. In this case, a difference between shapes may be put into numerical form. A program of checking a layout symmetry constraint may be adapted so that the processing section 101 determines that there is not an error, if the numetrical form that indicates a difference between the shapes of elements falls within the allowance range.

In each of the above-described first to seventh embodiments, the symmetry axis is assumed to be parallel to the Y axis or the X axis. Alternatively, the symmetry axis may be any arbitrary straight line. In this case, instead of the procedure of checking whether or not the X or Y coordinates of the centers of gravity of a symmetrical element pair match and the procedure of checking whether or not the X or Y coordinates of the midpoints of the line segments between the centers of gravity of symmetrical element pairs match, it may be checked whether or not the midpoint of a line segment between the centers of gravity of a symmetrical element pair included in a layout symmetry constraint is located on a straight line of a symmetry axis and the line segment between the centers of gravity of the symmetrical element pair is orthogonal with respect to the straight line.

When it is checked whether or not the shapes of elements match in each of the above-described embodiments, a program of checking a layout symmetry constraint may be set so that the processing section 101 determines that there is not an error when the shapes match without mirror symmetry, in addition to when the shapes are mirror-symmetrical with respect to a symmetry axis.

Although the element is a rectangle in each of the above-described embodiments, the element may be a polygon other than a rectangle. When the element is a polygon whose center of gravity is not easy to obtain, the element maybe represented using a rectangle which covers the polygon (in the case of a symmetrical element pair, an element, and another element which constitutes the symmetrical element pair with the former element, need to be covered with respective congruent rectangles), thereby making it possible to use the layout symmetry constraint checking method of the present invention.

In each of the above-described embodiments, one element is represented by one rectangle. Alternatively, for example, when a plurality of elements, such as a plurality of transistors sharing a diffusion layer or the like, are placed in a single group, such a group of elements can be represented by one rectangle.

When a distance between elements is limited to a predetermined range in design, the distance between elements may be set in the checking process using the third check process and the symmetry axis in the present invention, thereby making it possible to limit the distance within the predetermined range.

When a symmetrical element pair requires the same current direction with respect to a symmetry axis, a procedure of checking whether or not current directions match is provided in addition to the process of checking whether or not the shapes of elements match, thereby making it possible to determine a placement of elements in which the current directions are symmetrical with respect to the symmetry axis.

According to the layout symmetry constraint checking method and apparatus of the present invention, a layout symmetry constraint can be efficiently checked, and therefore, can be applied to layout design of a semiconductor integrated circuit, such as an analog circuit, a digital circuit, or the like.

While the invention has been described in detail, the foregoing description is in all aspects illustrative and not restrictive. It is understood that numerous other modifications and variations can be devised without departing from the scope of the invention.

What is claimed is:

1. A method for checking symmetry of a placement of elements included in a circuit, comprising:
a layout symmetry constraint inputting step of inputting a layout symmetry constraint including information about a symmetrical element pair of two elements which should be placed symmetrical;
a layout data inputting step of inputting layout data including information about shapes of the elements and information about the placement of the elements;
a first checking step of checking whether or not the shapes of the elements constituting the symmetrical element pair match, based on the element shape information included in the layout data; and
a second checking step of obtaining a relative positional relationship between the elements based on the element placement information included in the layout data, and checking whether or not the relative positional relationship satisfies the layout symmetry constraint.

2. The method according to claim 1, wherein the layout symmetry constraint includes information about a symmetrical element pair of two elements which should be placed line-symmetrical with respect to a symmetry axis.

3. The method according to claim 2, further comprising a third checking step of checking whether or not a geometric placement of the elements satisfies the layout symmetry constraint, based on the element placement information included in the layout data.

4. The method according to claim 3, wherein the layout symmetry constraint further includes information about a self-symmetrical element which should be placed itself symmetrical with respect to the symmetry axis.

5. The method according to claim 2, wherein the first checking step includes checking whether or not X or Y coordinates of representative points of the elements constituting the symmetrical element pair match when a two-dimensional placement of the elements included in the layout data is represented by a Cartesian coordinate system in which the symmetry axis is a Y axis or an X axis.

6. The method according to claim 3, wherein the third checking step checks whether or not a midpoint of a line segment between representative points of the elements constituting the symmetrical element pair is located on the symmetry axis.

7. The method according to claim 4, wherein the third checking step checks whether or not a representative point of the self-symmetrical element is located on the symmetry axis.

8. The method according to claim 3, wherein the second checking step uses a sequence pair to represent the relative positional relationship between the elements, and uses the sequence pair to check whether or not the relative positional relationship of the elements satisfies the layout symmetry constraint.

9. The method according to claim 3, wherein the second checking step uses a first graph indicating a horizontal positional relationship between the elements and a second graph indicating a vertical positional relationship between the elements to represent the relative positional relationship between the elements, and uses the first graph and the second graph to check whether or not the relative positional relationship between the elements satisfies the layout symmetry constraint.

10. The method according to claim 1, wherein the second checking step uses eight directions to represent the relative positional relationship between the elements, the eight directions including top, bottom, left, right, upper right, lower left, upper left, and lower right, and uses the eight directions to check whether or not the relative positional relationship between the elements satisfies the layout symmetry constraint.

11. The method according to claim 3, wherein:
the layout data includes information about wiring lines connecting the elements and information about a symmetrical wiring line pair which should be placed symmetrical with respect to the symmetry axis; and
the method further comprises checking symmetry of the wiring lines.

12. The method according to claim 2, wherein the second checking step uses a sequence pair to represent the relative positional relationship between the elements, and uses the sequence pair to check the relative positional relationship between the elements satisfies the layout symmetry constraint.

13. The method according to claim 2, wherein the second checking step uses a first graph indicating a horizontal positional relationship between the elements and a second graph indicating a vertical positional relationship between the elements to represent the relative positional relationship between the elements, and uses the first graph and the second graph to check whether or not the relative positional relationship between the elements satisfies the layout symmetry constraint.

14. The method according to claim 1, wherein the layout symmetry constraint includes information about a symmetrical element pair of two elements which should be placed point-symmetrical with respect to a symmetry center.

15. The method according to claim 14, further comprising a third checking step of checking whether or not a geometric placement of the elements satisfies the layout symmetry constraint, based on the element placement information included in the layout data.

16. The method according to claim 15, wherein the layout symmetry constraint further includes information about a self-symmetrical element which should be placed itself symmetrical with respect to the symmetry center.

17. The method according to claim 14, wherein the first checking step includes checking whether or not X and Y coordinates of a midpoint of a line segment between representative points of the elements constituting the symmetrical element pair match the symmetry center when a two-dimensional placement of the elements included in the layout data is represented by a Cartesian coordinate system.

18. The method according to claim 15, wherein the third checking step checks whether or not a midpoint of a line segment between representative points of the elements constituting the symmetrical element pair is located on the symmetry center.

19. The method according to claim 16, wherein the third checking step checks whether or not a representative point of the self-symmetrical element is located on the symmetry center.

20. The method according to claim 15, wherein:
the layout data includes information about wiring lines connecting the elements and information about a symmetrical wiring line pair which should be placed symmetrical with respect to the symmetry center; and
the method further comprises checking symmetry of the wiring lines.

21. A method for checking symmetry of a placement of elements included in a circuit, comprising:
a layout symmetry constraint inputting step of inputting a layout symmetry constraint including information about a symmetrical element pair of two elements which should be placed symmetrical with respect to a center graphic;
a layout data inputting step of inputting layout data including information about shapes of the elements and information about the placement of the elements;
an element displaying step of displaying the placement of the elements based on the layout data;
a designating step of designating the center graphic defined in the layout symmetry constraint;
a center graphic displaying step of displaying the designated center graphic and the placement of the elements, wherein the designated center graphic and the placement of the elements are superposed together;
a first checking step of checking whether or not the shapes of the elements constituting the symmetrical element pair match, based on the element shape information included in the layout data; and
a second checking step of checking whether or not a geometric placement of all elements included in the layout symmetry constraint satisfies symmetry with respect to the center graphic.

22. The method according to claim 21, wherein:
the center graphic is a symmetry axis; and
the layout symmetry constraint includes information about a symmetrical element pair of two elements which should be placed symmetrical with respect to the symmetry axis.

23. The method according to claim 22, wherein the layout symmetry constraint further includes information about a self-symmetrical element which should be placed itself symmetrical with respect to the symmetry axis.

24. The method according to claim 22, further comprising a third checking step of obtaining a relative positional relationship between the elements based on the element placement information included in the layout data, and checking whether or not the relative positional relationship satisfies the layout symmetry constraint.

25. The method according to claim 21, wherein:
the center graphic is a symmetry center; and
the layout symmetry constraint includes information about a symmetrical element pair of two elements which should be placed point-symmetrical with respect to the symmetry center.

26. The method according to claim 25, wherein the layout symmetry constraint further includes information about a self-symmetrical element which should be placed itself symmetrical with respect to the symmetry center.

27. The method according to claim 25, further comprising a third checking step of obtaining a relative positional relationship between the elements based on the element placement information included in the layout data, and checking whether or not the relative positional relationship satisfies the layout symmetry constraint.

28. An apparatus for checking symmetry of a placement of elements included in a circuit, comprising:
layout symmetry constraint inputting means of inputting a layout symmetry constraint including information about a symmetrical element pair of two elements which should be placed symmetrical;
layout data inputting means of inputting layout data including information about shapes of the elements and information about the placement of the elements;
first checking means of checking whether or not the shapes of the elements constituting the symmetrical element pair match, based on the element shape information included in the layout data; and
second checking means of obtaining a relative positional relationship between the elements based on the element placement information included in the layout data, and checking whether or not the relative positional relationship satisfies the layout symmetry constraint.

29. The apparatus according to claim 28, further comprising third checking means of checking whether or not a geometric placement of the elements satisfies the layout symmetry constraint, based on the element placement information included in the layout data.

30. The apparatus according to claim 28, wherein the layout symmetry constraint includes information about a symmetrical element pair of two elements which should be placed line-symmetrical with respect to a symmetry axis.

31. The apparatus according to claim 30, wherein the layout symmetry constraint further includes information about a self-symmetrical element which should be placed itself symmetrical with respect to the symmetry axis.

32. The apparatus according to claim 30, wherein the first checking means includes means of checking whether or not X or Y coordinates of representative points of the elements constituting the symmetrical element pair match when a two-dimensional placement of the elements included in the layout data is represented by a Cartesian coordinate system in which the symmetry axis is a Y axis or an X axis.

33. The apparatus according to claim 28, wherein the layout symmetry constraint includes information about a symmetrical element pair of two elements which should be placed point-symmetrical with respect to a symmetry center.

34. The apparatus according to claim 33, wherein the layout symmetry constraint further includes information about a self-symmetrical element which should be placed itself symmetrical with respect to the symmetry center.

35. The apparatus according to claim 33, wherein the first checking means includes means of checking whether or not X and Y coordinates of a midpoint of a line segment between representative points of the elements constituting the symmetrical element pair match the symmetry center when a two-dimensional placement of the elements included in the layout data is represented by a Cartesian coordinate system.

36. An apparatus for checking symmetry of a placement of elements included in a circuit, comprising:
layout symmetry constraint inputting means of inputting a layout symmetry constraint including information about a symmetrical element pair of two elements which should be placed symmetrical with respect to a center graphic;
layout data inputting means of inputting layout data including information about shapes of the elements and information about the placement of the elements;
element displaying means of displaying the placement of the elements based on the layout data;
designating means of designating the center graphic defined in the layout symmetry constraint;
center graphic displaying means of displaying the designated center graphic and the placement of the elements, wherein the designated center graphic and the placement of the elements are superposed together;
first checking means of checking whether or not the shapes of the elements constituting the symmetrical element pair match, based on the element shape information included in the layout data; and
second checking means of checking whether or not a geometric placement of all elements included in the layout symmetry constraint satisfies symmetry with respect to the center graphic.

37. The apparatus according to claim 36, wherein:
the center graphic is a symmetry axis; and
the layout symmetry constraint includes information about a symmetrical element pair of two elements which should be placed symmetrical with respect to the symmetry axis.

38. The apparatus according to claim 37, wherein the layout symmetry constraint further includes information about a self-symmetrical element which should be placed itself symmetrical with respect to the symmetry axis.

39. The apparatus according to claim 37, further comprising third checking means of obtaining a relative positional relationship between the elements based on the element placement information included in the layout data, and checking whether or not the relative positional relationship satisfies the layout symmetry constraint.

40. The apparatus according to claim 36, wherein:
the center graphic is a symmetry center; and
the layout symmetry constraint includes information about a symmetrical element pair of two elements which should be placed point-symmetrical with respect to the symmetry center.

41. The apparatus according to claim 40, wherein the layout symmetry constraint further includes information about a self-symmetrical element which should be placed itself symmetrical with respect to the symmetry center.

42. The apparatus according to claim 40, further comprising third checking means of obtaining a relative positional relationship between the elements based on the element placement information included in the layout data, and checking whether or not the relative positional relationship satisfies the layout symmetry constraint.
